(19) United States
(12) Patent Application Publication
(10) Pub. No.: US 2024/0315109 A1
(43) Pub. Date: Sep. 19, 2024

(54) Displays that Overlap Light Sensors

(71) Applicant: Apple Inc., Cupertino, CA (US)

(72) Inventors: Lixia Zhou, Sunnyvale, CA (US); Joy M Johnson, San Francisco, CA (US); Sandeep Chalasani, San Jose, CA (US); Ting Sun, Cupertino, CA (US); Yang Deng, San Jose, CA (US); Majid Gharghi, San Carlos, CA (US); Majid Esfandyarpour, Redwood City, CA (US); Young Cheol Yang, Sunnyvale, CA (US); Yuchi Che, Santa Clara, CA (US); Warren S Rieutort-Louis, Cupertino, CA (US); Kyounghwan Kim, San Jose, CA (US); Sebastian Knitter, San Francisco, CA (US); Yi Qiao, San Jose, CA (US); Jean-Pierre S Guillou, La Jolla, CA (US); Ze Yuan, Fremont, CA (US); Adam Backer, Albany, NY (US); Yi-Pai Huang, Zhubei (TW); Chaohao Wang, Shanghai (CN)

(21) Appl. No.: 18/571,105

(22) PCT Filed: Apr. 26, 2022
(86) PCT No.: PCT/US22/26394

§ 371 Date: Dec. 15, 2023

Related U.S. Application Data
(60) Provisional application No. 63/217,975, filed on Jul. 2, 2021.

(51) Int. Cl. H10K 59/65; H10K 59/131

(52) U.S. Cl. CPC H10K 59/65; H10K 59/131

(57) ABSTRACT

An electronic device may include a display and an optical sensor formed underneath the display. The electronic device may include a locally modified region that overlaps the optical sensor. The locally modified region of the display may have a modification relative to a normal region of the display that does not overlap the optical sensor. The modification may mitigate diffractive artifacts that would otherwise impact the optical sensor that senses light passing through the display. To mitigate diffraction artifacts, the locally modified region of the display may use spatial randomization (e.g., spatial randomization of signal paths and/or spatial randomization of via locations), opaque structures may be formed with circular footprints, a black masking layer may be formed with circular openings, apodization may be used, and/or a phase randomization film may be included.

This application claims priority to U.S. provisional patent application No. 63/217,975, filed Jul. 2, 2021, which is hereby incorporated by reference herein in its entirety.

### BACKGROUND

This relates generally to electronic devices, and, more particularly, to electronic devices with displays.

Electronic devices often include displays. For example, an electronic device may have a light-emitting diode (LED) display based on light-emitting diode pixels. In this type of display, each pixel includes a light-emitting diode and thin-film transistors for controlling application of a signal to the light-emitting diode to produce light.

There is a trend towards borderless electronic devices with a full-face display. These devices, however, may still need to include sensors such as cameras, ambient light sensors, and proximity sensors to provide other device capabilities.

It is within this context that the embodiments herein arise.

### SUMMARY

An electronic device may include a display and an optical sensor formed underneath the display. The electronic device may include a locally modified region that overlaps the optical sensor. The locally modified region of the display may have a modification relative to a normal region of the display that does not overlap the optical sensor. The modification may mitigate diffractive artifacts that would otherwise impact the optical sensor that senses light passing through the display.

In the normal region of the display, opaque components of the display such as signal lines, vias, LEDs, and/or black masking layer may have a periodic layout. Periodic structures of this type may contribute to diffraction artifacts for a sensor that senses light passing through the display. To mitigate diffraction artifacts, the locally modified region of the display may use spatial randomization. For example, spatial randomization of signal paths and/or spatial randomization of via locations may be used to mitigate periodicity of the opaque structures in the display. Additionally, forming opaque structures with circular footprints instead of rectangular footprints may mitigate diffraction artifacts.

A black masking layer may be formed with circular openings to mitigate diffraction artifacts. Apodization (a smooth transition in transparency between opaque and transparent portions of the display) may also mitigate diffraction artifacts. Phase randomization is yet another technique that may be used to mitigate diffraction artifacts.

### BRIEF DESCRIPTION OF THE DRAWINGS

FIG. 1 is a schematic diagram of an illustrative electronic device having a display and one or more sensors in accordance with an embodiment.

FIG. 2 is a schematic diagram of an illustrative display with light-emitting elements in accordance with an embodiment.

FIG. 3 is a diagram of an illustrative display pixel circuit in accordance with an embodiment.

FIG. 4 is a cross-sectional side view of an illustrative display with light-emitting diodes on a transparent substrate that overlaps a sensor in accordance with an embodiment.

FIG. 5 is a top view of an illustrative display with light-emitting diodes on a transparent substrate in accordance with an embodiment.

FIG. 6 is a top view of an illustrative opaque footprint of a display in accordance with an embodiment.

FIGS. 7A and 7B are top views showing the appearance of a point light source viewed through a display in accordance with an embodiment.

FIGS. 8A-8F are top views of illustrative displays showing possible positions for locally modified regions in accordance with an embodiment.

FIG. 9 is a top view of an illustrative periodic layout for horizontally extending portions and vertically extending portions of an opaque footprint of a display in accordance with an embodiment.

FIG. 10 is a top view of an illustrative locally modified region of a display with a non-periodic layout for horizontally extending portions and vertically extending portions of an opaque footprint in accordance with an embodiment.

FIG. 11 is a top view of an illustrative locally modified region of a display having an opaque footprint with random zig-zag horizontally extending portions and vertically extending portions in accordance with an embodiment.

FIG. 12 is a top view of an illustrative vertically extending portion of an opaque footprint of a display that follows a random zig-zag path in accordance with an embodiment.

FIG. 13 is a top view of an illustrative locally modified region of a display having vias that are randomly shifted to reduce periodicity in accordance with an embodiment.

FIG. 14 is a top view of an illustrative locally modified region of a display having circular opaque LED and via patches to mitigate diffraction artifacts in accordance with an embodiment.

FIGS. 15A-15C are top views of opaque footprints for an illustrative display showing how a black masking layer with circular openings may at least partially define the opaque footprint in accordance with an embodiment.

FIGS. 16A-16C are top views of opaque footprints for an illustrative display

showing how a black masking layer may have circular openings with each circular opening overlapping two pixel apertures in accordance with an embodiment.

FIG. 17 is a top view of an illustrative black masking layer for a display that has randomly sized and randomly positioned circular openings to mitigate diffraction artifacts in accordance with an embodiment.

FIG. 18A is a top view of an illustrative opaque footprint of a display that includes apodization in accordance with an embodiment.

FIG. 18B is a graph of light transmission as a function of position for portions of an illustrative display that do and do not include apodization in accordance with an embodiment.

FIG. 19 is a cross-sectional side view of an illustrative phase randomization film that may be incorporated into a display in accordance with an embodiment.

FIG. 20 is a cross-sectional side view of an illustrative display stack with a pixel removal region having a transparent opening in accordance with an embodiment.

FIG. 21 is a top view of an illustrative display with transparent openings that overlap a sensor in accordance with an embodiment.

FIG. 22 is a top view of an illustrative pixel removal region in a display that has one thin-film transistor sub-pixel for each emissive sub-pixel in accordance with an embodiment.

FIG. 23 is a top view of an illustrative display having cathode openings that are defined by random outlines in accordance with an embodiment.

FIG. 24 is a top view of an illustrative display having transparent signal lines in accordance with an embodiment.

FIG. 25 is a cross-sectional side view of an illustrative display having transparent signal lines and a corresponding phase compensation layer in accordance with an embodiment.

FIG. 26 is a top view of an illustrative display having transparent signal lines and dummy layers for phase compensation in accordance with an embodiment.

FIG. 27 is a cross-sectional side view of an illustrative display having a dummy transparent conductive layer for phase compensation in accordance with an embodiment.

FIG. 28 is a cross-sectional side view of an illustrative display having a patterned dielectric layer for phase compensation in accordance with an embodiment.

FIG. 29 is a cross-sectional side view of an illustrative display having both a dummy transparent conductive layer and a patterned dielectric layer for phase compensation in accordance with an embodiment.

FIGS. 30A and 30B are top views of a prior art display.

### DETAILED DESCRIPTION

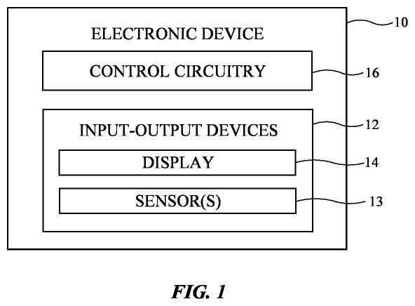

An illustrative electronic device of the type that may be provided with a display is shown in FIG. 1. Electronic device 10 may be a computing device such as a laptop computer, a computer monitor containing an embedded computer, a tablet computer, a cellular telephone, a media player, or other handheld or portable electronic device, a smaller device such as a wrist-watch device, a pendant device, a headphone or earpiece device, a device embedded in eyeglasses or other equipment worn on a user's head, or other wearable or miniature device, a display, a computer display that contains an embedded computer, a computer display that does not contain an embedded computer, a gaming device, a navigation device, an embedded system such as a system in which electronic equipment with a display is mounted in a kiosk or automobile, or other electronic equipment. Electronic device 10 may have the shape of a pair of eyeglasses (e.g., supporting frames), may form a housing having a helmet shape, or may have other configurations to help in mounting and securing the components of one or more displays on the head or near the eye of a user.

As shown in FIG. 1, electronic device 10 may include control circuitry 16 for supporting the operation of device 10. Control circuitry 16 may include storage such as hard disk drive storage, nonvolatile memory (e.g., flash memory or other electrically-programmable-read-only memory configured to form a solid-state drive), volatile memory (e.g., static or dynamic random-access memory), etc. Processing circuitry in control circuitry 16 may be used to control the operation of device 10. The processing circuitry may be based on one or more microprocessors, microcontrollers, digital signal processors, baseband processors, power management units, audio chips, application-specific integrated circuits, etc.

Input-output circuitry in device 10 such as input-output devices 12 may be used to allow data to be supplied to device 10 and to allow data to be provided from device 10 to external devices. Input-output devices 12 may include buttons, joysticks, scrolling wheels, touch pads, key pads, keyboards, microphones, speakers, tone generators, vibrators, cameras, sensors, light-emitting diodes and other status indicators, data ports, etc. A user can control the operation of device 10 by supplying commands through input resources of input-output devices 12 and may receive status information and other output from device 10 using the output resources of input-output devices 12.

Input-output devices 12 may include one or more displays such as display 14. Display 14 may be a touch screen display that includes a touch sensor for gathering touch input from a user or display 14 may be insensitive to touch. A touch sensor for display 14 may be based on an array of capacitive touch sensor electrodes, acoustic touch sensor structures, resistive touch components, force-based touch sensor structures, a light-based touch sensor, or other suitable touch sensor arrangements. A touch sensor for display 14 may be formed from electrodes formed on a common display substrate with the display pixels of display 14 or may be formed from a separate touch sensor panel that overlaps the pixels of display 14. If desired, display 14 may be insensitive to touch (i.e., the touch sensor may be omitted). Display 14 in electronic device 10 may be a head-up display that can be viewed without requiring users to look away from a typical viewpoint or may be a head-mounted display that is incorporated into a device that is worn on a user's head. If desired, display 14 may also be a holographic display used to display holograms.

Control circuitry 16 may be used to run software on device 10 such as operating system code and applications. During operation of device 10, the software running on control circuitry 16 may display images on display 14.

Input-output devices 12 may also include one or more sensors 13 such as force sensors (e.g., strain gauges, capacitive force sensors, resistive force sensors, etc.), audio sensors such as microphones, touch and/or proximity sensors such as capacitive sensors (e.g., a two-dimensional capacitive touch sensor associated with a display and/or a touch sensor that forms a button, trackpad, or other input device not associated with a display), and other sensors. In accordance with some embodiments, sensors 13 may include optical sensors such as optical sensors that emit and detect light (e.g., optical proximity sensors such as transreflective optical proximity structures), ultrasonic sensors, and/or other touch and/or proximity sensors, monochromatic and color ambient light sensors, image sensors, fingerprint sensors, temperature sensors, proximity sensors and other sensors for measuring three-dimensional non-contact gestures (“air gestures”), pressure sensors, sensors for detecting position, orientation, and/or motion (e.g., accelerometers, magnetic sensors such as compass sensors, gyroscopes, and/or inertial measurement units that contain some or all of these sensors), health sensors, radio-frequency sensors, depth sensors (e.g., structured light sensors and/or depth sensors based on stereo imaging devices), optical sensors such as self-mixing sensors and light detection and ranging (lidar) sensors that gather time-of-flight measurements, humidity sensors, moisture sensors, gaze tracking sensors, and/or other sensors. In some arrangements, device 10 may use sensors 13 and/or other input-output devices to gather user input (e.g., buttons may be used to gather button press input, touch sensors overlapping displays can be used for gathering user touch screen input, touch pads may be used in gathering touch input, microphones may be used for gathering audio input, accelerometers may be used in monitoring when a finger contacts an input surface and may therefore be used to gather finger press input, etc.).

Display 14 may be a light-emitting diode display or may be a display based on other types of display technology (e.g., liquid crystal displays). Device configurations in which display 14 is a light-emitting diode display are sometimes described herein as an example. This is, however, merely illustrative. Any suitable type of display may be used, if desired. In general, display 14 may have a rectangular shape (i.e., display 14 may have a rectangular footprint and a rectangular peripheral edge that runs around the rectangular footprint) or may have other suitable shapes. Display 14 may be planar or may have a curved profile.

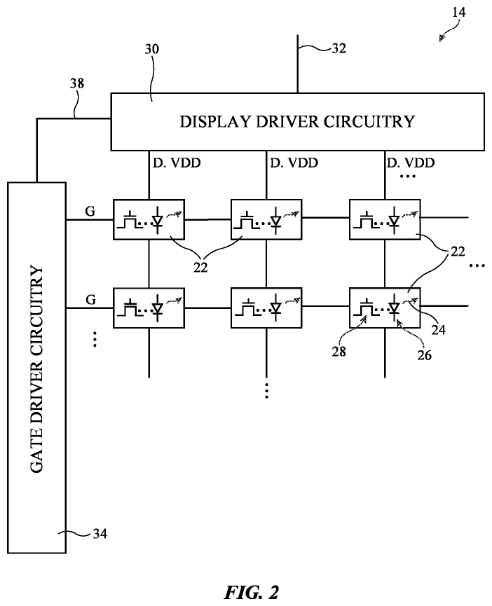

A top view of a portion of display 14 is shown in FIG. 2. As shown in FIG. 2, display 14 may have an array of pixels 22 formed on a substrate. Pixels 22 may receive data signals over signal paths such as data lines D and may receive one or more control signals over control signal paths such as horizontal control lines G (sometimes referred to as gate lines, scan lines, emission control lines, etc.). There may be any suitable number of rows and columns of pixels 22 in display 14 (e.g., tens or more, hundreds or more, or thousands or more). Each pixel 22 may include a light-emitting diode 26 that emits light 24 under the control of a pixel control circuit formed from thin-film transistor circuitry such as thin-film transistors 28 and thin-film capacitors. Thin-film transistors 28 may be polysilicon thin-film transistors, semiconducting-oxide thin-film transistors such as indium zinc gallium oxide (IGZO) transistors, or thin-film transistors formed from other semiconductors. Pixels 22 may contain light-emitting diodes of different colors (e.g., red, green, and blue) to provide display 14 with the ability to display color images or may be monochromatic pixels.

Display driver circuitry may be used to control the operation of pixels 22. The display driver circuitry may be formed from integrated circuits, thin-film transistor circuits, or other suitable circuitry. Display driver circuitry 30 of FIG. 2 may contain communications circuitry for communicating with system control circuitry such as control circuitry 16 of FIG. 1 over path 32. Path 32 may be formed from traces on a flexible printed circuit or other cable. During operation, the control circuitry (e.g., control circuitry 16 of FIG. 1) may supply display driver circuitry 30 with information on images to be displayed on display 14.

To display the images on display pixels 22, display driver circuitry 30 may supply image data to data lines D while issuing clock signals and other control signals to supporting display driver circuitry such as gate driver circuitry 34 over path 38. If desired, display driver circuitry 30 may also supply clock signals and other control signals to gate driver circuitry 34 on an opposing edge of display 14.

Gate driver circuitry 34 (sometimes referred to as row control circuitry) may be implemented as part of an integrated circuit and/or may be implemented using thin-film transistor circuitry. Horizontal control lines G in display 14 may carry gate line signals such as scan line signals, emission enable control signals, and other horizontal control signals for controlling the display pixels 22 of each row. There may be any suitable number of horizontal control signals per row of pixels 22 (e.g., one or more row control signals, two or more row control signals, three or more row control signals, four or more row control signals, etc.).

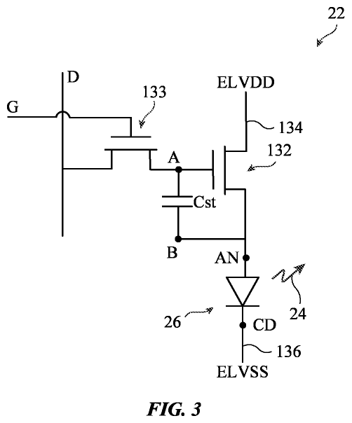

A schematic diagram of an illustrative pixel circuit of the type that may be used for each pixel 22 in display 14 is shown in FIG. 3. As shown in FIG. 3, display pixel 22 may include light-emitting diode 26. A positive power supply voltage ELVDD may be supplied to positive power supply terminal 134 and a ground power supply voltage ELVSS may be supplied to ground power supply terminal 136. Diode 26 has an anode (terminal AN) and a cathode (terminal CD). The state of drive transistor 132 controls the amount of current flowing through diode 26 and therefore the amount of emitted light 24 from display pixel 22. Cathode CD of diode 26 is coupled to ground terminal 136, so cathode terminal CD of diode 26 may sometimes be referred to as the ground terminal for diode 26.

To ensure that transistor 132 is held in a desired state between successive frames of data, display pixel 22 may include a storage capacitor such as storage capacitor Cst. The voltage on storage capacitor Cst is applied to the gate of transistor 132 at node A to control transistor 132. Data can be loaded into storage capacitor Cst using one or more switching transistors such as switching transistor 133. When switching transistor 133 is off, data line D is isolated from storage capacitor Cst and the gate voltage on terminal A is equal to the data value stored in storage capacitor Cst (i.e., the data value from the previous frame of display data being displayed on display 14). When gate line G (sometimes referred to as a scan line) in the row associated with display pixel 22 is asserted, switching transistor 133 will be turned on and a new data signal on data line D will be loaded into storage capacitor Cst. The new signal on capacitor Cst is applied to the gate of transistor 132 at node A, thereby adjusting the state of transistor 132 and adjusting the corresponding amount of light 24 that is emitted by light-emitting diode 26. If desired, the circuitry for controlling the operation of light-emitting diodes for display pixels in display 14 (e.g., transistors, capacitors, etc. in display pixel circuits such as the display pixel circuit of FIG. 3) may be formed using other configurations (e.g., configurations that include circuitry for compensating for threshold voltage variations in drive transistor 132, etc.). The display pixel may include additional switching transistors, emission transistors in series with the drive transistor, etc. Capacitor Cst may be positioned at other desired locations within the pixel (e.g., between the source and gate of the drive transistor). The display pixel circuit of FIG. 3 is merely illustrative.

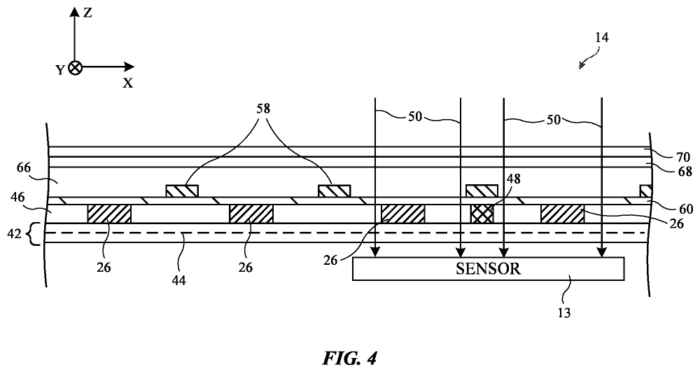

FIG. 4 is a cross-sectional side view of an illustrative display that includes light-emitting diodes and that is formed over a sensor. As shown, a plurality of light-emitting diodes 26 may be formed on a substrate such as substrate 42. Substrate 42 may include glass layers, polymer layers, silicon layers, composite films that include polymer and inorganic materials, metallic foils, etc. Substrate 42 may have a transparency of incident light (e.g., visible light and/or infrared light) that is greater than 50%, greater than 70%, greater than 80%, greater than 90%, greater than 95%, greater than 99%, etc. Substrate 42 may therefore sometimes be referred to as transparent substrate 42.

Each light-emitting diode 26 may be a micro-light-emitting diode (e.g., a light-emitting diode semiconductor die having a footprint of about 10 microns×10 microns, more than 5 microns×5 microns, less than 100 microns×100 microns, less than 20 microns×20 microns, less than 10 microns×10 microns, or other desired size). This example is merely illustrative, and light-emitting diodes 26 may also be organic light-emitting diodes (OLED) that include a plurality of OLED layers. The light-emitting diode may be electrically connected to thin-film circuitry within substrate 42. In one example, the light-emitting diode may be soldered to substrate 42.

Substrate 42 may include thin-film transistors, contact pads (e.g., exposed conductive layers to which LEDs 26 are soldered), and/or signal lines such as signal lines 44. Signal lines 44 may include gate lines (such as gate lines G in FIG. 2), data lines (such as data lines D in FIG. 2), power supply lines, etc. The signal lines may be formed from conductive layers on an outer surface of substrate or may be embedded within substrate 42. The signal lines and other circuitry within substrate 42 may be used to control the LEDs 26.

The light-emitting diodes 26 may be surrounded by planarization layer 46. Planarization layer 64 (sometimes referred to as diffuser layer 64, overcoat layer 64, etc.) may optionally include a plurality of light scattering particles distributed throughout a host material. The host material may be a transparent polymer (e.g., a siloxane). The light scattering particles may be formed from metal oxide (e.g., titanium dioxide) or another desired material. The light scattering particles may have a different index of refraction than the host material. Light incident upon the light scattering particles may therefore be scattered in a random direction. In general, one or more diffusive layers may be incorporated at any desired location within the display stack.

A cathode layer 60 may be formed over the light-emitting diodes 26 and may serve as the cathode terminal (e.g., cathode terminal CD in FIG. 3) for light-emitting diodes 26. The cathode layer may serve as the cathode for multiple light-emitting diodes and is therefore formed as a blanket layer across the display. Cathode layer 60 may therefore sometimes be referred to as a common electrode. The cathode layer may be formed from a transparent conductive material (e.g., indium tin oxide).

LEDs 26 may be soldered to exposed electrodes on an upper surface of substrate 42. These exposed electrodes may serve as anode terminals for the LEDs (e.g., anode terminal AN in FIG. 3). The exposed electrodes may be referred to as anode electrodes or simply anodes.

An opaque masking layer 58 (sometimes referred to as black masking layer 58, black mask 58, opaque mask 58, etc.) is formed over the substrate 42. The opaque masking layer 58 may be patterned to include openings that each overlap a respective one of the light-emitting diodes 26. Each opening in opaque masking layer 58 over a respective light-emitting diode allows light from that light-emitting diode to pass through the opening towards the viewer (e.g., in the positive Z-direction). Elsewhere (e.g., over portions of planarization layer 46 between pixels), the opaque masking layer may block light (e.g., to prevent cross-talk between adjacent pixels, to mitigate reflections off underlying signal lines, etc.). The opaque masking layer 58 may transmit less than 10% of incident light (at a wavelength associated with light emitted from LED 26, at a visible wavelength, and/or at an infrared wavelength), less than 5% of incident light, less than 3% of incident light, less than 1% of incident light, etc. The opaque masking layer may be formed from any desired material (e.g., an organic or inorganic opaque material).

An overcoat layer 66 may be formed over the LEDs 26 and masking layer 58. Overcoat layer 66 may optionally have a low index of refraction. Overcoat layer 66 may be formed from an acrylate based organic material, an epoxy based organic material, or any other desired material. These examples are merely illustrative and in general any desired organic or inorganic material may be used for overcoat layer 66.

Additional layers may be formed over overcoat 66. As shown in FIG. 4, a polarizer 68 and transparent cover layer 70 may be formed over the overcoat layer. Polarizer 68 may be a linear polarizer or a circular polarizer. Transparent cover layer 70 may be a transparent layer (e.g., formed from glass or plastic) that protects the display. The transparent cover layer 70 may be the outer-most layer of the display (and electronic device) if desired. One or more additional layers may be included in the display if desired (e.g., between overcoat layer 66 and transparent cover layer 70 or above transparent cover layer 70).

The display may also include one or more conductive vias 48. The conductive vias 48 may electrically connect cathode 60 to power supply lines within substrate 42, as an example. Conductive via 48 may be formed as a separate metal layer from cathode 60. Alternatively, planarization layer 46 may be etched to have an opening (via) that is subsequently filled by cathode 60. In this scenario, cathode 60 directly contacts a contact pad on substrate 42 through the opening in planarization layer 46. Conductive vias 48 may be included across the display to ensure that cathode 60 remains at a target power supply voltage across the display.

The region on display 14 where the display pixels 22 are formed may sometimes be referred to herein as the active area. Electronic device 10 has an external housing with a peripheral edge. The region surrounding the active area and within the peripheral edge of device 10 is the border region. Images can only be displayed to a user of the device in the active region. It is generally desirable to minimize the border region of device 10. For example, device 10 may be provided with a full-face display 14 that extends across the entire front face of the device. If desired, display 14 may also wrap around over the edge of the front face so that at least part of the lateral edges or at least part of the back surface of device 10 is used for display purposes.

To incorporate sensors without reducing the size of the active area, device 10 may include one or more sensors 13 mounted behind display 14 (e.g., behind the active area of the display). FIG. 4 shows how, because substrate 42 is transparent, light 50 may pass through display 14 to reach sensor 13. Sensor 13 therefore obtains sensor data without reducing the size of the active area of the display or otherwise increasing the footprint of the electronic device. As described above in connection with FIG. 1, sensor 13 may be an optical sensor such as a camera, proximity sensor, ambient light sensor, fingerprint sensor, or other light-based sensor. An output device (e.g., a light-emitting component that emits infrared light) may also be used instead of sensor 13 if desired. In general, any desired input-output device may be positioned behind the display and may operate through the display.

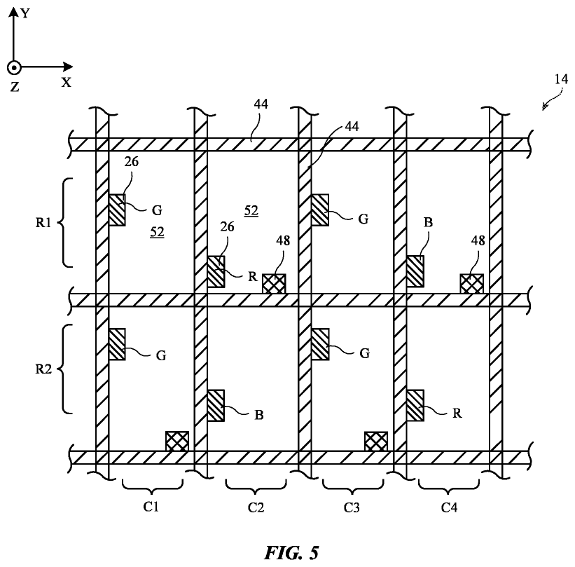

FIG. 5 is a top view of display 14 showing a periodic layout for the display. In the example of FIG. 5, signal lines 44 (such as data lines, gate lines, power supply lines, etc.) are arranged in a grid. The grid of signal lines defines a plurality of openings 52 (sometimes referred to as apertures 52, pixel openings 52, or pixel apertures 52). A corresponding LED 26 may be formed within each aperture 52. The display also includes a plurality of vias 48. The vias may be arranged in every other pixel within a given row, as an example.

The LEDs 26 may be arranged in a zig-zag pattern (as shown in FIG. 5). In FIG. 5, the first row (R1) includes red, green, and blue LEDs arranged in a zig-zag pattern. Similarly, the second row (R2) includes red, green, and blue LEDs arranged in a zig-zag pattern. Some of the columns (e.g., columns C1 and C3) include all green LEDs. Some of the columns (e.g., columns C2 and C4) alternate between red LEDs and green LEDs.

The arrangement of FIG. 5 may be referred to as a periodic arrangement. The spacing and pattern of the components in FIG. 5 are consistent according to a repetitive pattern. Each aperture 52 may therefore have the same or approximately the same (e.g., within 5%) dimensions. The vias 48 may be arranged in a consistent, periodic pattern. The LED layout follows a consistent, periodic, zig-zag pattern.

Having a periodic layout in this way may improve the ease of manufacturing the display. However, periodic structures of this type may contribute to diffraction artifacts for a sensor that senses light passing through the display.

The opaque components of display 14 may define an opaque footprint for the display (e.g., an opaque footprint on transparent substrate 42). The opaque footprint of the display may be defined by one or more of the opaque layers or components within the display (e.g., signal lines 44, LEDs 26, vias 48, and/or black masking layer 58). The portions of the display within the opaque footprint may be substantially opaque (e.g., may transmit less than 40% of incident light, may transmit less than 30% of incident light, may transmit less than 20% of incident light, may transmit less than 10% of incident light, may transmit less than 5% of incident light, may transmit less than 1% of incident light, etc.). The portions of the display outside of the opaque footprint may be substantially transparent (may transmit more than 70% of incident light, may transmit more than 80% of incident light, may transmit more than 90% of incident light, may transmit more than 95% of incident light, may transmit more than 99% of incident light, etc.).

The overall area of the opaque footprint of the display may be less than 80% of the total area of the display, less than 50% of the total area of the display, less than 40% of the total area of the display, less than 30% of the total area of the display, less than 20% of the total area of the display, less than 10% of the total area of the display, etc. Reducing the overall area occupied by the opaque footprint may desirably increase the overall transparency of the display, which improves the performance of the underlying sensor 13. However, reducing the area of the opaque footprint may require reducing the display resolution, may increase manufacturing costs, etc.

It should be noted that, to mitigate undesired reflections, black masking layer 58 may be patterned to overlap one or more other opaque components in the display (such as signal lines 44 and/or vias 48). The black masking layer 58 therefore may at least partially define the opaque footprint of the display.

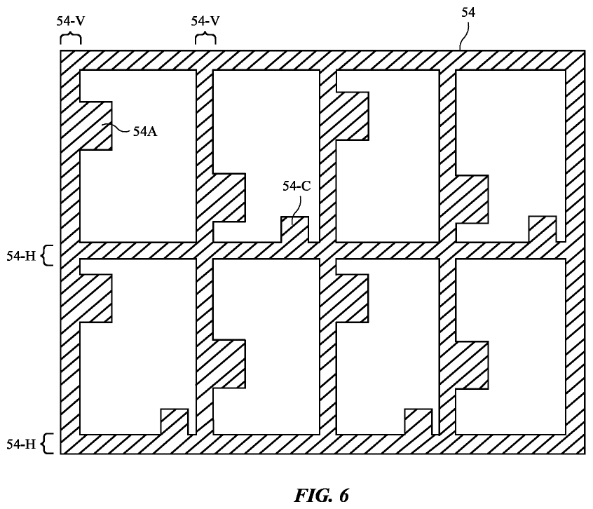

In some cases, the opaque footprint of the display may be periodic. FIG. 6 is a top view of the opaque footprint 54 associated with the display layout shown in FIG. 5. As shown in FIG. 6, opaque footprint 54 has regular, repeating shapes (caused by the periodic layout of apertures 52, LEDs 26, and vias 48). These repetitive, opaque structures with small transparent gaps between them may create visible artifacts when sensing light through the display. Diffraction of environmental light that passes through the display to sensor 13 results in undesirable visible artifacts such as rainbow effects and diffraction spikes.

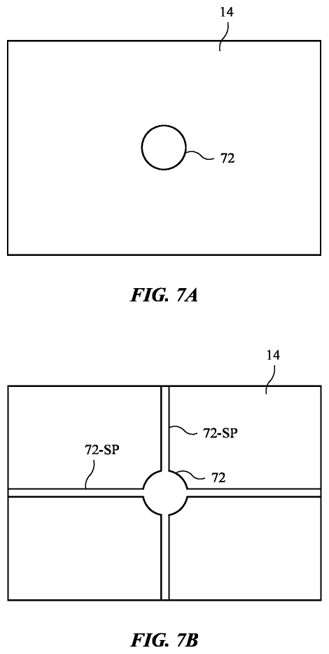

An example of these diffraction effects is shown in FIGS. 7A and 7B. In particular, consider the example of a point light source that is viewed through display 14 by sensor 13. When sensed by sensor 13, the point light source should (ideally) appear as a circular area of light. FIG. 7A shows an example of this type, with the light from the point source appearing over area 72. In FIG. 7A (e.g., in an ideal scenario where no diffraction artifacts are present), area 72 has a circular shape without additional spikes or rainbow effects. In practice, the repeating structures of FIG. 5 may result in area 72 having an appearance as shown in FIG. 7B. As shown, area 72 in FIG. 7B includes spike portions 72-SP in addition to a circular portion.

These types of diffractive artifacts are undesirable. There are numerous ways to mitigate these types of diffraction artifacts while still including the requisite opaque components of the display. To mitigate diffraction artifacts, the shapes of the opaque footprint of the display may be selected to include non-periodic portions (e.g., to include randomness and reduce periodicity), the display may include shapes selected to mitigate diffraction artifacts, the opaque footprint may include apodization, and/or the display may include high-index material that causes phase randomization.

In some cases, the majority of the display may have a periodic layout (with a corresponding periodic opaque footprint) as shown in FIGS. 5 and 6. In areas of the display that do not transmit light for an underlying sensor 13, the periodicity of the layout may not cause any adverse effects. However, in areas of the display that transmit light for an underlying sensor 13, the display may be modified to mitigate diffraction artifacts.

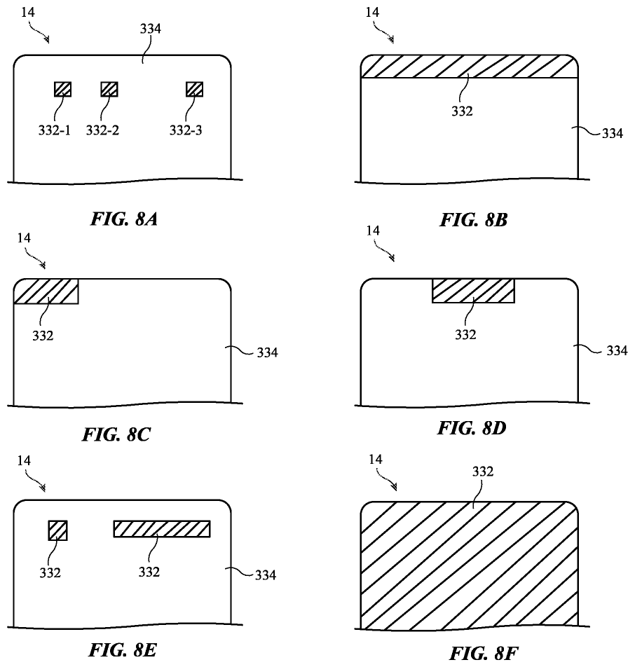

In general, the display may be modified to mitigate diffraction artifacts in any region(s) of display 14. FIGS. 8A-8F are front views showing how display 14 may have one or more locally modified regions in which the display is modified to mitigate diffraction artifacts. The example of FIG. 8A illustrates various locally modified regions 332 physically separated from one another (i.e., the various locally modified regions 332 are non-continuous) by normal display region 334. The locally modified regions 332 may have some modification relative to normal display region 334 that mitigates diffraction artifacts. These regions may therefore sometimes be referred to as diffraction-artifact-mitigation regions 332, non-periodic regions 332, reduced periodicity regions 332, etc. The normal display region 334 may have a periodic layout (associated with diffraction artifacts) and therefore may sometimes be referred to as periodic region 334, unmodified region 334, etc.

The three locally modified regions 332-1, 332-2, and 332-3 in FIG. 8A might for example correspond to three different sensors formed underneath display 14 (with one sensor per locally modified region). Any portion of the display that is within the field-of-view of an underlying sensor may be modified to mitigate diffraction artifacts.

The example of FIG. 8B illustrates a continuous locally modified region 332 formed along the top border of display 14, which might be suitable when there are many optical sensors positioned near the top edge of device 10. The example of FIG. 8C illustrates a locally modified region 332 formed at a corner of display 14 (e.g., a rounded corner area of the display). In some arrangements, the corner of display 14 in which locally modified region 332 is located may be a rounded corner (as in FIG. 8C) or a corner having a substantially 90° corner. The example of FIG. 8D illustrates a locally modified region 332 formed only in the center portion along the top edge of device 10 (i.e., the locally modified region covers a recessed notch area in the display). FIG. 8E illustrates another example in which locally modified regions 332 can have different shapes and sizes. FIG. 8F illustrates yet another suitable example in which the locally modified region covers the entire display surface. In other words, the entire display may have non-periodic or diffraction-mitigating structures as will be later discussed. These examples are merely illustrative and are not intended to limit the scope of the present embodiments. If desired, any one or more portions of the display overlapping with optically based sensors or other sub-display electrical components may be designated as a locally modified region to mitigate diffraction artifacts.

One option for mitigating diffraction artifacts in the locally modified region(s) 332 is to reduce periodicity of the opaque footprint in the locally modified region. The spacing of one or more components within the display may therefore be randomized within the locally modified region to mitigate diffraction artifacts.

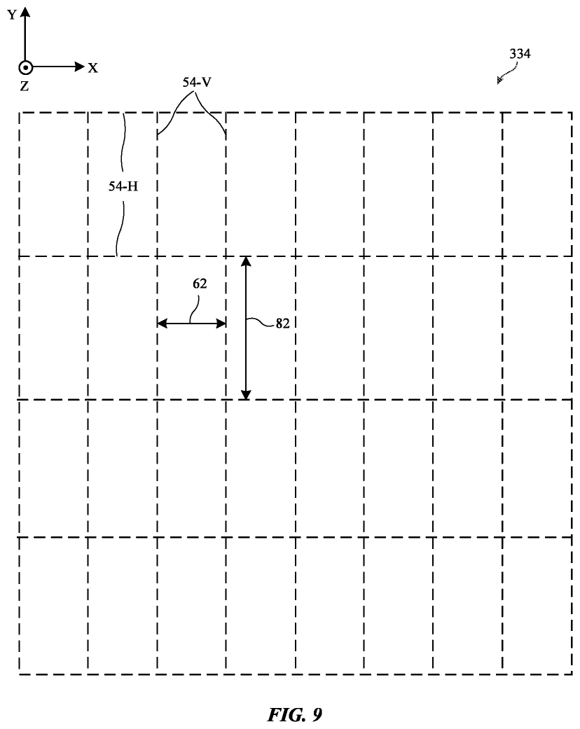

As shown in with FIG. 6, the opaque footprint includes vertically extending portions 54-V and horizontally extending portions 54-H that form a grid. FIG. 9 is a top view of a normal display region 334 showing how the horizontally extending portions and vertical extending portions may have a regular, periodic spacing in the normal display region. In other words, the horizontal distance 62 (e.g., the separation in the X-direction) between each vertically extending portion 54-V is constant across the normal display region 334. Similarly, the vertical distance 82 (e.g., the separation in the Y-direction) between each horizontally extending portion 54-H is constant across the normal display region 334.

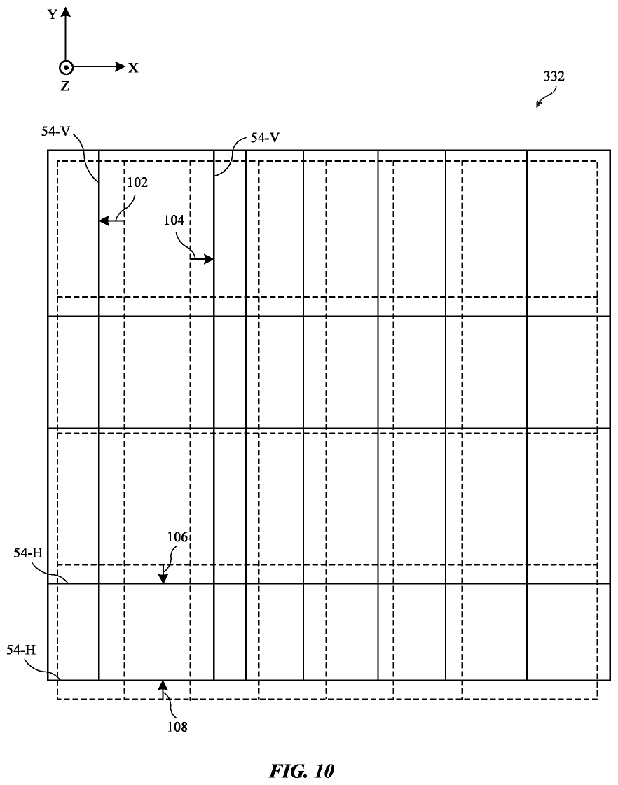

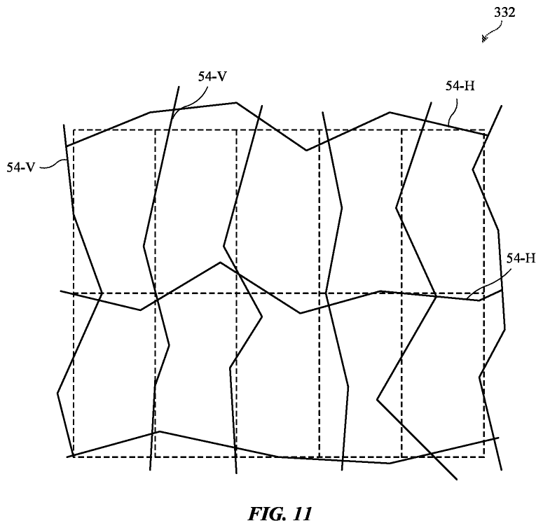

To mitigate periodicity, each horizontally extending portion and vertically extending portion of the opaque footprint (and, correspondingly, the signal lines and/or black masking layer that define the opaque footprint) may be randomly shifted from the periodic layout position. In FIG. 10, the periodic layout grid is shown by the dashed lines. Each vertically extending portion of the opaque footprint may be randomly shifted from its corresponding periodic position. For example, a first vertically extending portion 54-V is shifted by distance 102 in the negative X-direction. A second vertically extending portion 54-V is shifted by distance 104 in the positive X-direction. The shift distance of each vertically extending portion along the X-axis may be randomly selected from a predetermined range. The predetermined range may be defined in absolute terms (e.g., a distance in micron) or in relative terms (e.g., as a percentage of periodic pitch 62 from FIG. 9). The shift distance range may be greater than or equal to ±1 micron, greater than or equal to ±0.5 micron, greater than or equal to ±2 micron, greater than or equal to ±3 micron, greater than or equal to ±5 micron, greater than or equal to ±10 micron, greater than or equal to ±20 micron, greater than or equal to ±30 micron, greater than or equal to ±50 micron, greater than or equal to ±100 micron, greater than or equal to ±500 micron, less than or equal to ±10 micron, less than or equal to ±20 micron, less than or equal to ±30 micron, between ±5 micron and ±15 micron, etc. The shift distance range may be greater than or equal to ±10% of the pitch, greater than or equal to ±15% of the pitch, greater than or equal to ±5% of the pitch, greater than or equal to ±20% of the pitch, greater than or equal to ±25% of the pitch, greater than or equal to ±30% of the pitch, greater than or equal to ±40% of the pitch, less than or equal to ±40% of the pitch, between ±10% of the pitch and ±40% of the pitch, etc.

Each horizontally extending portion of the opaque footprint may be randomly shifted from its corresponding periodic position. For example, a first vertically extending portion 54-H is shifted by distance 106 in the negative Y-direction. A second vertically extending portion 54-H is shifted by distance 108 in the positive Y-direction. The shift distance of each vertically extending portion along the Y-axis may be randomly selected from a predetermined range. The predetermined range may be defined in absolute terms (e.g., a distance in micron) or in relative terms (e.g., as a percentage of periodic pitch 82 from FIG. 9). The shift distance range may be greater than or equal to ±1 micron, greater than or equal to ±0.5 micron, greater than or equal to ±2 micron, greater than or equal to ±3 micron, greater than or equal to ±5 micron, greater than or equal to ±10 micron, greater than or equal to ±20 micron, greater than or equal to ±30 micron, greater than or equal to ±50 micron, greater than or equal to ±100 micron, greater than or equal to ±500 micron, less than or equal to ±10 micron, less than or equal to ±20 micron, less than or equal to ±30 micron, between ±5 micron and ±15 micron, etc. The shift distance range may be greater than or equal to ±10% of the pitch, greater than or equal to ±15% of the pitch, greater than or equal to ±5% of the pitch, greater than or equal to ±20% of the pitch, greater than or equal to ±25% of the pitch, greater than or equal to ±30% of the pitch, greater than or equal to ±40% of the pitch, less than or equal to ±40% of the pitch, between ±10% of the pitch and ±40% of the pitch, etc.

Randomizing the position of the horizontally extending portions and the vertically extending portions of the opaque footprint (and, correspondingly, the signal lines and/or black masking layer that define the opaque footprint) mitigates periodicity in the display (and, correspondingly, diffraction artifacts in a sensor that senses light through the display).

In FIGS. 6, 9, and 10, the horizontally extending portions and the vertically extending portions of the opaque footprint are straight lines (linear). Another option to reduce periodicity and mitigate diffraction artifacts is to instead form zig-zag horizontally extending portions and zig-zag vertically extending portions for the opaque footprint. FIG. 11 is a top view of an opaque footprint with zig-zag horizontally extending portions and zig-zag vertically extending portions.

In FIG. 11, the periodic layout grid is shown by the dashed lines. Each vertically extending portion 54-V of the opaque footprint has a zig-zag shape with various segments that are angled relative to the linear periodic position. The zig-zag vertically extending portions may optionally stay within a predetermined range from its corresponding periodic position. The total predetermined range (relative to the linear periodic grid) may be greater than or equal to ±1 micron, greater than or equal to ±0.5 micron, greater than or equal to ±2 micron, greater than or equal to ±3 micron, greater than or equal to ±5 micron, greater than or equal to ±10 micron, greater than or equal to ±20 micron, greater than or equal to ±30 micron, greater than or equal to ±50 micron, greater than or equal to ±100 micron, greater than or equal to ±500 micron, less than or equal to ±10 micron, less than or equal to ±20 micron, less than or equal to ±30 micron, between ±5 micron and ±15 micron, etc. The predetermined range may be greater than or equal to ±10% of the pitch, greater than or equal to ±15% of the pitch, greater than or equal to ±5% of the pitch, greater than or equal to ±20% of the pitch, greater than or equal to ±25% of the pitch, greater than or equal to ±30% of the pitch, greater than or equal to ±40% of the pitch, less than or equal to ±40% of the pitch, between ±10% of the pitch and ±40% of the pitch, etc.

As shown in FIG. 11, each horizontally extending portion 54-H of the opaque footprint has a zig-zag shape with various segments that are angled relative to the linear periodic position. The zig-zag horizontally extending portions may optionally stay within a predetermined range from its corresponding periodic position. The total predetermined range (relative to the linear periodic grid) may be greater than or equal to ±1 micron, greater than or equal to ±0.5 micron, greater than or equal to ±2 micron, greater than or equal to ±3 micron, greater than or equal to ±5 micron, greater than or equal to ±10 micron, greater than or equal to ±20 micron, greater than or equal to ±30 micron, greater than or equal to ±50 micron, greater than or equal to ±100 micron, greater than or equal to ±500 micron, less than or equal to ±10 micron, less than or equal to ±20 micron, less than or equal to ±30 micron, between ±5 micron and ±15 micron, etc. The predetermined range may be greater than or equal to ±10% of the pitch, greater than or equal to ±15% of the pitch, greater than or equal to ±5% of the pitch, greater than or equal to ±20% of the pitch, greater than or equal to ±25% of the pitch, greater than or equal to ±30% of the pitch, greater than or equal to ±40% of the pitch, less than or equal to ±40% of the pitch, between ±10% of the pitch and ±40% of the pitch, etc.

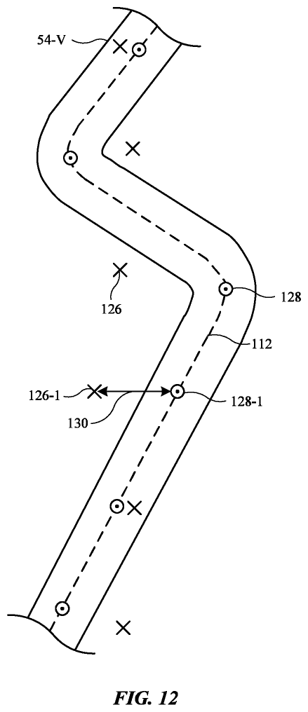

The zig-zag portions of the opaque footprint in FIG. 11 may follow random zig-zag paths (with each segment having a random angle and/or length). FIG. 12 is a top view of a vertically extending portion 54-V having a random shape (e.g., following a random path). Introducing randomness into the shape of the vertically extending portion may break the periodicity of the opaque footprint and reduce diffractive artifacts.

To produce the vertically extending portion 54-V having a random shape, a reference line may be adjusted in a random fashion. As shown in FIG. 12, a reference line may have a number of reference points 126 (marked by an x in FIG. 12). Each reference point 126 is at a different point along the reference line. The reference points may be distributed along the periodic grid as shown by the dashed grid in FIG. 11, for example. The reference points 126 may be evenly or unevenly distributed along the reference line. In FIG. 12, the reference points 126 are depicted as being evenly distributed along the reference line.

To generate the random shape, an additional point 128 (sometimes referred to as axis point 128 or anchor point 128) may be generated that is associated with each reference point 126. Each additional point 128 may be shifted relative to reference point 126 in a direction orthogonal to the reference line by a random amount. For example, point 128-1 has been shifted away from point 126-1 by a distance 130.

The shift distance 130 for each axis point 128 may be randomly selected from a predetermined range. The predetermined range may be defined in absolute terms (e.g., a distance in micron) or in relative terms (e.g., a percentage of the length of the interconnect portion in the event the interconnect portion is a straight line between two adjacent component mounting portions). The shift distance range may be greater than or equal to ±1 micron, greater than or equal to ±0.5 micron, greater than or equal to ±2 micron, greater than or equal to ±3 micron, greater than or equal to ±5 micron, greater than or equal to ±10 micron, greater than or equal to ±20 micron, greater than or equal to ±30 micron, greater than or equal to ±50 micron, greater than or equal to ±100 micron, greater than or equal to ±500 micron, less than or equal to ±10 micron, less than or equal to ±20 micron, less than or equal to ±30 micron, between ±5 micron and ±15 micron, etc. The shift distance range may be greater than or equal to ±10% of the pitch, greater than or equal to ±15% of the pitch, greater than or equal to ±5% of the pitch, greater than or equal to ±20% of the pitch, greater than or equal to ±25% of the pitch, greater than or equal to ±30% of the pitch, greater than or equal to ±40% of the pitch, less than or equal to ±40% of the pitch, between ±10% of the pitch and ±40% of the pitch, etc.

In some cases, the shift distance may be randomly selected to be 0. In this case, the axis point 128 will be the same as reference point 126. The axis 112 of the randomly shaped vertically extending portion 54-V (and corresponding signal lines and/or black masking layer) may pass through each randomly generated axis point 128. The axis may be straight or curved between each axis point. The vertically extending portion therefore follows a random axis (path).

Any desired number of reference points (and corresponding randomly generated anchor points) may be used to form the randomly shaped vertically extending portion 54-V. The example in FIG. 12 of the reference points being evenly distributed along the reference line is merely illustrative. If desired, the reference points may be unevenly distributed (e.g., randomly distributed) along the reference line for additional randomness.

This type of technique may be also used to determine a random zig-zag shape for each horizontally extending portion of the opaque footprint.

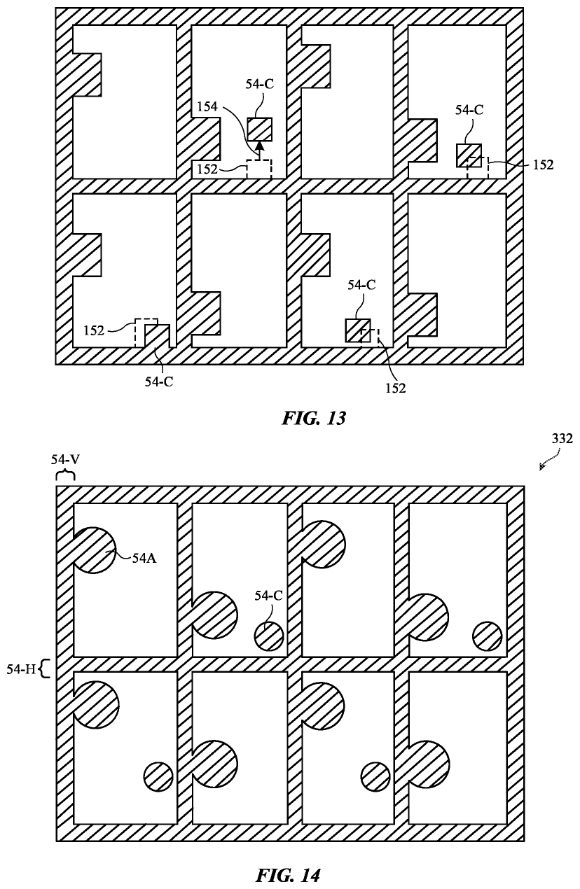

Another way to reduce periodicity in the opaque footprint is to randomize the position of the vias in the display. As shown in FIG. 6, in the normal portion of the display, the opaque footprint may have portions 54-C that overlap vias in the display (e.g., vias that electrically connect the cathode layer to thin-film transistor circuitry in the substrate). Portions 54-C of the opaque footprint may be caused by the vias themselves and/or black masking layer that is patterned to cover the vias. In the normal portion of the display, the vias may follow a periodic pattern. The periodic pattern is shown in FIG. 13 by the dashed boxes.

The periodic pattern (used in normal display region 334) may have consistent horizontal and vertical spacing between each adjacent pair of vias. In the locally modified region 332 of the display, the vias may be randomly positioned (e.g., by shifting the via in a random direction by a random distance from the corresponding periodic position 152). FIG. 13 shows how a via-covering portion of the opaque footprint 54-C may be shifted in direction 154 from periodic position 152. Any desired range of shift direction and shift distance may be used when shifting the vias from their corresponding periodic layout positions.

After the randomization of the via positions in the locally modified region of the display, there may be inconsistent horizontal and vertical spacing between each adjacent pair of vias. For example, the horizontal pitch between two adjacent vias in a first row is different than the horizontal pitch between two adjacent vias in a second, different row. In normal display region 334, the center-to-center spacing between adjacent vias in the horizontal direction (e.g., along the X-axis) may be consistent (e.g., there is only 1 unique center-to-center spacing used). In contrast, in locally modified region 332, there may be a plurality of unique center-to-center spacings between adjacent vias (e.g., at least three unique center-to-center spacings, at least five unique center-to-center spacings, at least eight unique center-to-center spacings, at least ten unique center-to-center spacings, at least twenty unique center-to-center spacings, at least fifty unique center-to-center spacings, etc.). It should be noted that normal manufacturing variation between the center-to-center spacing (e.g., center-to-center spacing variations within 5%, within 3%, within 1%, etc.) are not categorized as ‘unique center-to-center spacings’ for these purposes.

FIG. 6 shows how, in the normal portion of the display, the opaque footprint may have portions 54-C that overlap vias in the display (e.g., vias 48 that electrically connect the cathode layer to thin-film transistor circuitry in the substrate) and portions 54-A that overlap the LEDs 26 in the display. Portions 54-A of the opaque footprint may be defined by the LED itself, an electrode to which the LED is mounted, and/or other opaque layers formed over or under the LED.

Yet another way to reduce diffraction artifacts is to form portions 54-C and 54-A with a circular shape. FIG. 14 is a top view of an opaque footprint for the display in locally modified region 332 where portions 54-C and 54-A are circular. Using a circular shape for these portions of the opaque footprint may mitigate diffraction artifacts in a sensor operating through the display. The example of circles being used for opaque portions 54-C and 54-A is merely illustrative. These opaque portions may have other shapes (e.g., non-rectangular shapes) that mitigate diffraction artifacts if desired.

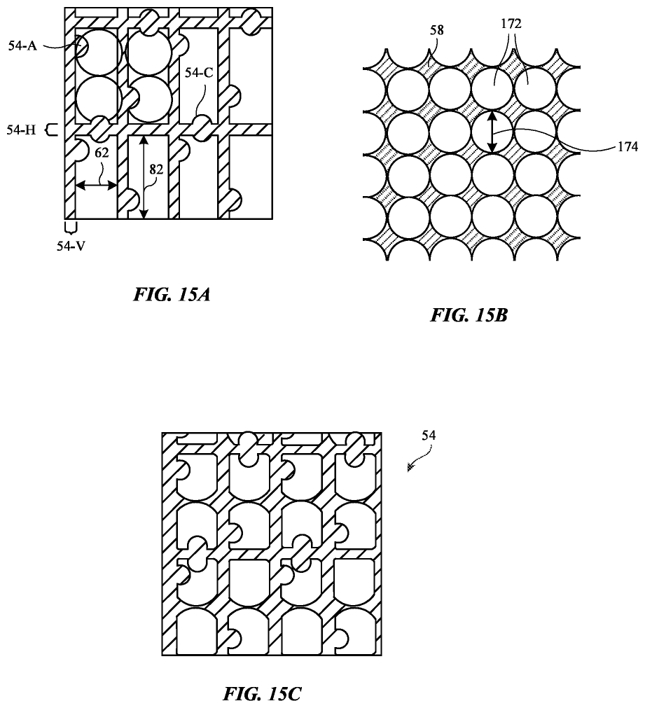

FIGS. 15A-15C show another option for mitigating diffraction artifacts in the locally modified region 332. FIG. 15A is a top view of an opaque footprint of the display caused by vertically extending portions 54-V, horizontally extending portions 54-H, LED portions 54-A, and via portions 54-C. The display may have this layout in both normal display region 334 and locally modified display region 332. In the normal display region, black masking layer 58 may be patterned to have a similar footprint as the footprint of FIG. 15A. In the locally modified display region, the black masking layer 58 may be patterned to have a plurality of circular openings as shown in FIG. 15B.

As shown in FIGS. 15A and 15B, each circular opening has a diameter 174 that is approximately equal to (e.g., within 20% of, within 10% of, within 5% of, etc.) the horizontal pitch 62 of vertically extending portions 54-V. Diameter 174 may also be approximately equal to (e.g., within 20% of, within 10% of, within 5% of, etc.) half of the vertical pitch 82 of horizontally extending portions 54-H. There are therefore two black mask openings 172 that overlap each aperture in the opaque footprint. The total opaque footprint 54 is shown in FIG. 15C. The total opaque footprint includes the openings in the black masking layer superimposed on the opaque footprint of FIG. 15A. Including the circular openings 172 in the opaque footprint mitigates diffraction artifacts in light sensed through the display. The example of circles being used for the shape of openings 172 is merely illustrative. These black mask openings may have other shapes (e.g., non-rectangular shapes) that mitigate diffraction artifacts if desired.

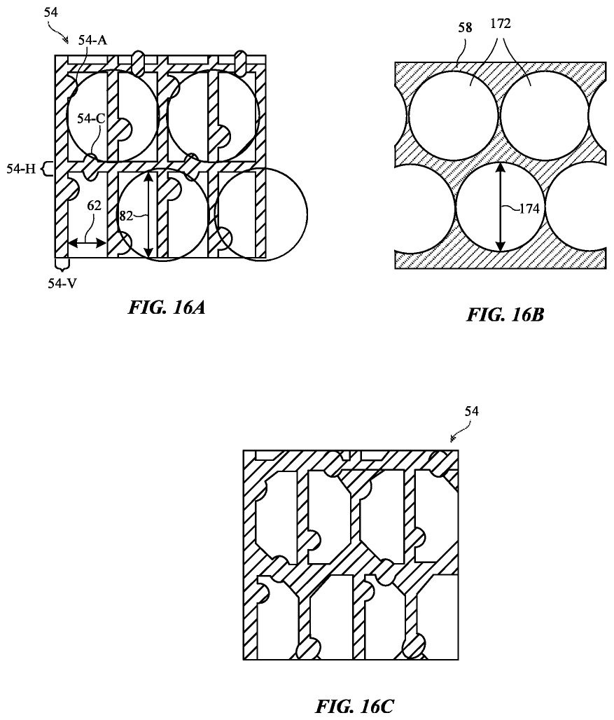

The example in FIGS. 15A-15C of two black mask openings overlapping each pixel aperture is merely illustrative. Another option, shown in FIGS. 16A-16C, is for one black mask opening to overlap two pixel apertures. As shown in FIGS. 16A and 16B, in this arrangement, each circular opening has a diameter 174 that is approximately equal to (e.g., within 20% of, within 10% of, within 5% of, etc.) double the horizontal pitch 62 of vertically extending portions 54-V. Diameter 174 may also be approximately equal to (e.g., within 20% of, within 10% of, within 5% of, etc.) the vertical pitch 82 of horizontally extending portions 54-H. There are therefore two pixel apertures overlapped by each circular opening in the black masking layer. The total opaque footprint 54 is shown in FIG. 16C. The total opaque footprint includes the openings in the black masking layer superimposed on the opaque footprint of FIG. 16A. Including the circular openings 172 in the opaque footprint mitigates diffraction artifacts in light sensed through the display. The example of circles being used for the shape of openings 172 is merely illustrative. These black mask openings may have other shapes (e.g., non-rectangular shapes) that mitigate diffraction artifacts if desired.

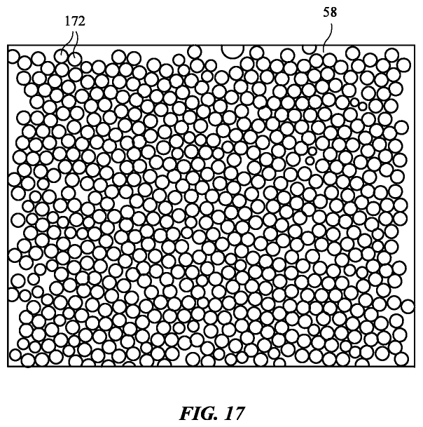

FIG. 17 is a top view of black masking layer 58 in locally modified region 332 showing how the black masking layer may be patterned with a random plurality of circular openings. The circular openings may have random sizes (within a predetermined range) and positions. There may be at least three unique diameters amongst the plurality of openings 172, at least five unique diameters amongst the plurality of openings 172, at least eight unique diameters amongst the plurality of openings 172, at least ten unique diameters amongst the plurality of openings 172, at least twenty unique diameters amongst the plurality of openings 172, at least fifty unique diameters amongst the plurality of openings 172, etc. Similarly, there may be a plurality of unique center-to-center spacings between adjacent openings amongst the plurality of openings (e.g., at least three unique center-to-center spacings, at least five unique center-to-center spacings, at least eight unique center-to-center spacings, at least ten unique center-to-center spacings, at least twenty unique center-to-center spacings, at least fifty unique center-to-center spacings, etc.). It should be noted that normal manufacturing variation between the diameters (e.g., diameter variations within 5%, within 3%, within 1%, etc.) are not categorized as ‘unique diameters’ for these purposes. Similarly, normal manufacturing variation between the center-to-center spacing (e.g., center-to-center spacing variations within 5%, within 3%, within 1%, etc.) are not categorized as ‘unique center-to-center spacings’ for these purposes. The example of circles being used for the shape of openings 172 in FIG. 17 is merely illustrative. These black mask openings may have other shapes (e.g., non-rectangular shapes) that mitigate diffraction artifacts if desired.

In addition to or instead of using any of the aforementioned techniques, apodization may be used to mitigate diffraction artifacts in a sensor operating through display 14. Apodization may refer to smoothly transitioning the opacity between the opaque portion and the transparent portion of the display. In the aforementioned examples, the opaque footprint has a given shape with a distinct border. The entire given shape (of the opaque footprint) is opaque and the surrounding area is transparent. There is therefore a sharp step in transparency between the opaque portion and the transparent portion. Apodization (sometimes referred to herein as transparency tapering or transparency smoothing) may be used to smooth out the transition between opaque and transparent portions.

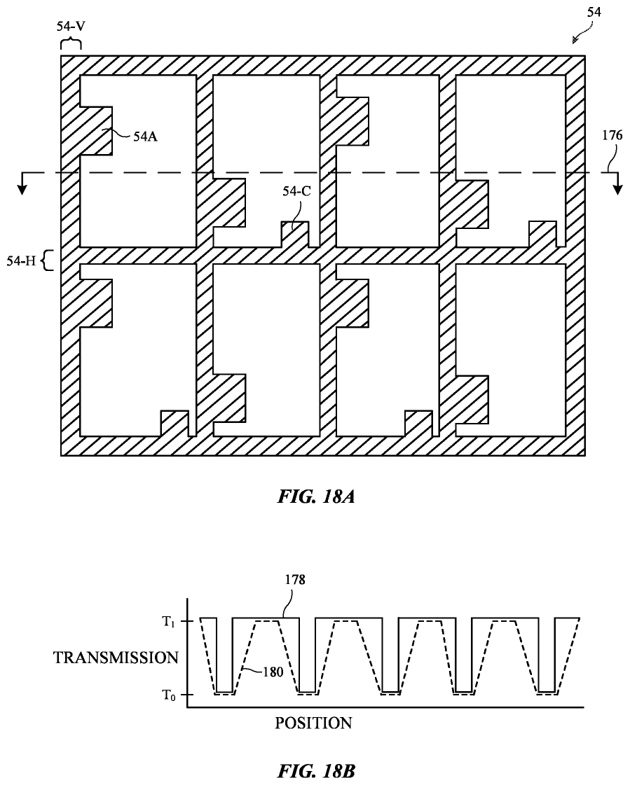

FIG. 18A is a top view of an opaque footprint 54 for the display (similar to as in FIG. 6). However, in FIG. 18A the opaque footprint may utilize apodization for diffraction mitigation. FIG. 18B is a graph of transmission through the display as a function of position (e.g., along line 176 in FIG. 18A). In the normal display region 334, the transmission may follow profile 178 that does not include apodization and therefore has sharp steps in transparency between the opaque portions (at T₀) and the transparent portions (at T₁) of the display. In the locally modified region 332, however, the opaque footprint includes apodization. There is therefore a gradual transition between each adjacent pair of opaque and transparent regions. The transparency may change gradually, continuously, and/or monotonically between each adjacent pair of opaque and transparent regions.

As one example, the aforementioned apodization may be achieved using black masking layer 58. The black masking layer 58 may be patterned to have apodization regions between the fully opaque regions and the fully transparent regions (where the black masking layer is not present). The black masking layer may have a varying thickness (with a maximum thickness in the maximum opacity region) to achieve the varying transparency and/or may be patterned with openings (with no openings in the maximum opacity region) to achieve the varying transparency.

In addition to or instead of any of the aforementioned techniques, phase randomization may be used to mitigate diffraction artifacts in a sensor operating through display 14. To randomize the phase of incident light passing through the display, a phase randomization film may be incorporated into the display.

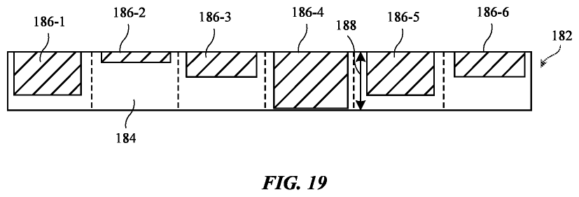

FIG. 19 is a cross-sectional side view of an illustrative phase randomization film that may be incorporated into the display. As shown, the phase randomization film 182 includes a plurality of high-index layers 186 formed in a low-index cladding 184 (sometimes referred to as base layer 184, surrounding layer 184, etc.). The high-index layers 186 may have a high index of refraction (e.g., greater than 1.3, greater than 1.4, greater than 1.5, greater than 1.6, greater than 1.7, greater than 1.8, etc.). The low-index cladding 184 may have a low index of refraction (e.g., less than 1.5, less than 1.4, less than 1.3, less than 1.2, etc.). The difference in refractive index between layers 186 and layer 184 may be greater than 0.1, greater than 0.2, greater than 0.3, greater than 0.4, greater than 0.5, between 0.1 and 0.5, less than 0.5, etc.

Each high-index layer may overlap one respective pixel aperture (e.g., aperture 52 in FIG. 5). In other words, each high-index layer has a footprint that is approximately the same as the footprint of a respective pixel aperture. Therefore, incident light passing through a respective pixel aperture also passes through that high-index layer. High-index layer 186-1 may overlap a first pixel aperture, high-index layer 186-2 may overlap a second pixel aperture, high-index layer 186-3 may overlap a third pixel aperture, etc.

Each high-index layer 186 may have a randomly selected thickness 188. The thickness 188 for each high-index layer may be selected from a predetermined range. The range may be greater than or equal to ±1 micron, greater than or equal to ±0.5 micron, greater than or equal to ±2 micron, greater than or equal to ±3 micron, greater than or equal to ±5 micron, greater than or equal to ±10 micron, greater than or equal to ±20 micron, greater than or equal to ±30 micron, greater than or equal to ±50 micron, greater than or equal to ±100 micron, greater than or equal to ±500 micron, less than or equal to ±10 micron, less than or equal to ±20 micron, less than or equal to ±30 micron, between ±5 micron and ±15 micron, etc.

To improve the ease and speed of manufacturing, there may be a set of unique thicknesses 188 from which the thickness for each high-index layer is randomly selected. As one example, there may be four possible thicknesses for the high-index layers. During manufacturing, there may be four deposition steps during which a layer of high-index material is deposited. For each pixel aperture, the phase randomization film may include zero, one, two, three, or four layers of the high-index material. For example, high-index layer 186-2 in FIG. 19 may be formed by one layer of the high-index material, high-index layers 186-3 and 186-6 in FIG. 19 may be formed by two layers of the high-index material, high-index layers 186-1 and 186-5 may be formed by three layers of the high-index material, and high-index layer 186-4 may be formed by four layers of the high-index material.

Instead of using multiple deposition steps to form the multiple thicknesses (as described above), the high-index layers may be formed using gray scale photolithography to have different thicknesses.

In general, there may be any desired number of unique thicknesses for the high-index layers in film 182 (e.g., two or more unique thicknesses, three or more unique thicknesses, four or more unique thicknesses, six or more unique thicknesses, eight or more unique thicknesses, ten or more unique thicknesses, twenty or more unique thicknesses, etc.). It should be noted that normal manufacturing variation between the layers (e.g., thickness variations within 5%, within 3%, within 1%, etc.) are not categorized as ‘unique thicknesses’ for these purposes.

Including phase randomization film 182 in the display stack causes light passing through the display to have different phases in different apertures, thus mitigating diffraction artifacts. The phase randomization film 182 may be incorporated at any desired location within the display stack (e.g., under transparent substrate 42, embedded within transparent substrate 42, over transparent substrate 42, under LEDs 26, over LEDs 26, coplanar with LEDs 26, over cathode 60 and under black masking layer 58, over black masking layer 58, over overcoat layer 66, etc.). An existing film/layer in the display stack may optionally be modified to serve the additional function of phase randomization. For example, planarization layer 46 and/or overcoat layer 66 may include high-index layers with randomized thicknesses in the pixel apertures to achieve the phase randomization.

The example in FIG. 19 of phase randomization film 182 including high-index layers 186 in a low-index cladding is merely illustrative. If desired, this arrangement may be inversed, with low-index layers having a varying thickness formed in a high-index cladding. The phase randomization film may have a uniform thickness. Therefore, randomized thicknesses of the high-index layers (as in FIG. 19) necessarily cause a randomized thickness in the low-index cladding. Similarly, if the arrangement is inversed, randomized thicknesses of the low-index layers would cause a randomized thickness in the high-index cladding. In both scenarios, there is a high-index material of a randomized thickness in the pixel aperture that causes phase randomization.

It should be noted that any or all of the aforementioned techniques to mitigate diffraction artifacts may be combined in a single display. Any subset or all techniques out of spatial randomization of routing paths (as in FIGS. 10-12), spatial randomization of via locations (as in FIG. 13), circular opaque LED and via patches (as in FIG. 14), circular black masking layer openings (as in FIGS. 15-17), apodization (as in FIGS. 18A and 18B), and phase randomization (as in FIG. 19) may be used in a single display.

Each locally modified region 332 in the display may include the same diffraction mitigation techniques or different locally modified regions may include some different diffraction mitigation techniques. In addition to the diffraction mitigation techniques, a locally modified region 332 may have addition modifications to increase the transparency of the display in the locally modified region (to increase the amount of light that reaches sensor 13, for example). For example, the locally modified region 332 may have a lower pixel resolution than in normal display region 334 (with some LEDs removed to improve transparency), more transparent materials may be used for certain components in locally modified region 332, etc.

As previously mentioned, LEDs 26 may be organic-light emitting diodes. In an OLED display, the locally modified portions 332 in the display may have pixels removed to increase transmission through the display. Regions of display 14 that at least partially cover or overlap with sensor(s) 13 in which at least a portion of the display pixels have been removed are sometimes referred to as pixel removal regions or pixel free regions. Removing display pixels (e.g., removing transistors and/or capacitors associated with one or more sub-pixels) in the pixel free regions can help increase transmission and improve the performance of the under-display sensor 13. In addition to removing display pixels, portions of additional layers may be removed for additional transmission improvement.

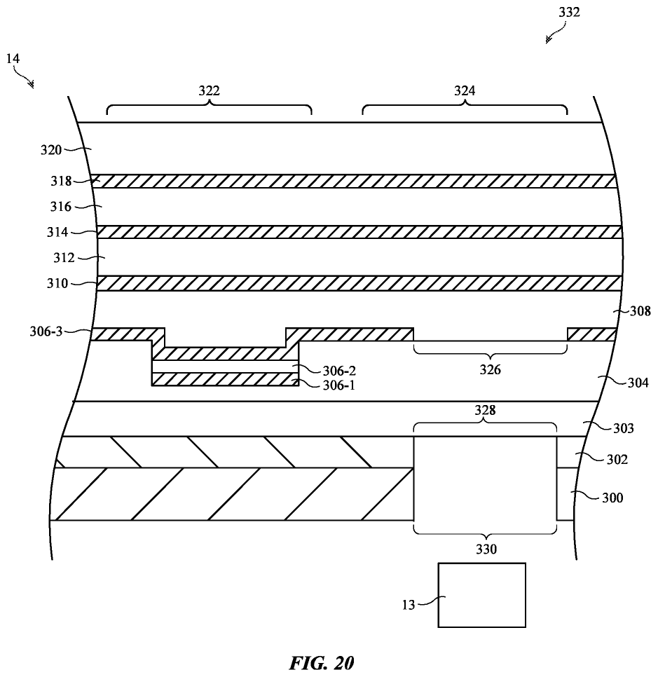

FIG. 20 is a cross-sectional side view of an illustrative pixel removal region of a display showing how pixels may be removed to increase transmission through the display. As shown in FIG. 20, the display stack may include a substrate such as substrate 300. Substrate 300 may be formed from glass, metal, plastic, ceramic, sapphire, or other suitable substrate materials. In some arrangements, substrate 300 may be an organic substrate formed from polyethylene terephthalate (PET) or polyethylene naphthalate (PEN) (as examples). One or more polyimide (PI) layers 302 may be formed over substrate 300. The polyimide layers may sometimes be referred to as an organic substrate (e.g., substrate 300 is a first substrate layer and substrate 302 is a second substrate layer). The surface of substrate 302 may optionally be covered with one or more buffer layers 303 (e.g., inorganic buffer layers such as layers of silicon oxide, silicon nitride, amorphous silicon, etc.).

Thin-film transistor (TFT) layers 304 may be formed over inorganic buffer layers 303 and organic substrates 302 and 300. The TFT layers 304 may include thin-film transistor circuitry such as thin-film transistors, thin-film capacitors, associated routing circuitry, and other thin-film structures formed within multiple metal routing layers and dielectric layers. Organic light-emitting diode (OLED) layers 306 may be formed over the TFT layers 304. The OLED layers 306 may include a diode cathode layer, a diode anode layer, and emissive material interposed between the cathode and anode layers. The OLED layers may include a pixel definition layer that defines the light-emitting area of each pixel. The TFT circuitry in layer 304 may be used to control an array of display pixels formed by the OLED layers 306.

Circuitry formed in the TFT layers 304 and the OLED layers 306 may be protected by encapsulation layers 308. As an example, encapsulation layers 308 may include a first inorganic encapsulation layer, an organic encapsulation layer formed on the first inorganic encapsulation layer, and a second inorganic encapsulation layer formed on the organic encapsulation layer. Encapsulation layers 308 formed in this way can help prevent moisture and other potential contaminants from damaging the conductive circuitry that is covered by layers 308. Substrate 300, polyimide layers 302, buffer layers 303, TFT layers 304, OLED layers 306, and encapsulation layers 308 may be collectively referred to as a display panel.

One or more polarizer films 312 may be formed over the encapsulation layers 308 using adhesive 310. Adhesive 310 may be implemented using optically clear adhesive (OCA) material that offer high light transmittance. One or more touch layers 316 that implement the touch sensor functions of touch-screen display 14 may be formed over polarizer films 312 using adhesive 314 (e.g., OCA material). For example, touch layers 316 may include horizontal touch sensor electrodes and vertical touch sensor electrodes collectively forming an array of capacitive touch sensor electrodes. Lastly, the display stack may be topped off with a cover glass layer 320 (sometimes referred to as a display cover layer 320) that is formed over the touch layers 316 using additional adhesive 318 (e.g., OCA material). Display cover layer 320 may be a transparent layer (e.g., transparent plastic or glass) that serves as an outer protective layer for display 14. The outer surface of display cover layer 320 may form an exterior surface of the display and the electronic device that includes the display.

As shown in FIG. 20, display 14 may include a locally modified region 332 (sometimes referred to as pixel removal region 332, reduced pixel density region 332, low pixel density region 332, etc.) with pixels removed. The pixel removal region may include some pixels (e.g., in pixel region 322) and some areas with removed components for increased transmittance (e.g., opening 324). Opening 324 has a higher transmittance than pixel region 322. Opening 324 may sometimes be referred to as high-transmittance area 324, window 324, display opening 324, display window 324, pixel-devoid region 324, etc. In the pixel region 322, the display may include a pixel formed from emissive material 306-2 that is interposed between an anode 306-1 and a cathode 306-3. Signals may be selectively applied to anode 306-1 to cause emissive material 306-2 to emit light for the pixel. Circuitry in thin-film transistor layer 304 may be used to control the signals applied to anode 306-1.

In display window 324, anode 306-1 and emissive material 306-2 may be omitted. Without the display window, an additional pixel may be formed in area 324 adjacent to the pixel in area 322 (according to the pixel pattern). However, to increase the transmittance of light to sensor 13 under the display, the pixel(s) in area 324 are removed. The absence of emissive material 306-2 and anode 306-1 may increase the transmittance through the display stack. Additional circuitry within thin-film transistor layer 304 may also be omitted in pixel removal area 332 to increase transmittance.

Additional transmission improvements through the display stack may be obtained by selectively removing additional components from the display stack in high-transmittance area 324. As shown in FIG. 20, a portion of cathode 306-3 may be removed in high-transmittance area 324. This results in an opening 326 in the cathode 306-3. Said another way, the cathode 306-3 may have conductive material that defines an opening 326 in the pixel removal region. Removing the cathode in this way allows for more light to pass through the display stack to sensor 13. Cathode 306-3 may be formed from any desired conductive material. The cathode may be removed via etching (e.g., laser etching or plasma etching). Alternatively, the cathode may be patterned to have an opening in pixel removal region 324 during the original cathode deposition and formation steps.

Polyimide layers 302 may be removed in high-transmittance area 324 in addition to cathode layer 306-3. The removal of the polyimide layers 302 results in an opening 328 in the pixel removal region. Said another way, the polyimide layer may have polyimide material that defines an opening 328 in the pixel removal region. The polyimide layers may be removed via etching (e.g., laser etching or plasma etching). Alternatively, the polyimide layers may be patterned to have an opening in high-transmittance area 324 during the original polyimide formation steps. Removing the polyimide layer 302 in high-transmittance area 324 may result in additional transmittance of light to sensor 13 in high-transmittance area 324.

Substrate 300 may be removed in high-transmittance area 324 in addition to cathode layer 306-3 and polyimide layer 302. The removal of the substrate 300 results in an opening 330 in the pixel removal region. Said another way, the substrate 300 may have material (e.g., PET, PEN, etc.) that defines an opening 330 in the pixel removal region. The substrate may be removed via etching (e.g., with a laser). Alternatively, the substrate may be patterned to have an opening in high-transmittance area 324 during the original substrate formation steps. Removing the substrate 300 in high-transmittance area 324 may result in additional transmittance of light to sensor 13 in high-transmittance area 324. The polyimide opening 328 and substrate opening 330 may be considered to form a single unitary opening. When removing portions of polyimide layer 302 and/or substrate 300, inorganic buffer layers 303 may serve as an etch stop for the etching step. Openings 328 and 330 may be filled with air or another desired transparent filler.

In addition to having openings in cathode 306-3, polyimide layers 302, and/or substrate 300, the polarizer 312 in the display may be bleached for additional transmittance in the pixel removal region.

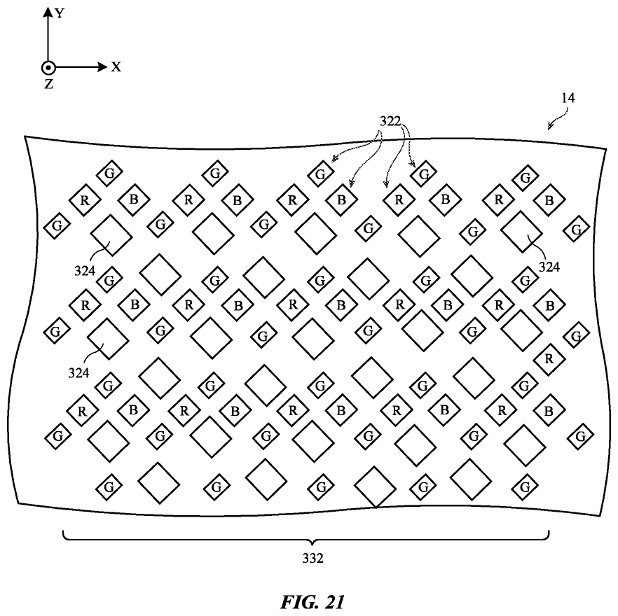

FIG. 21 is a top view of an illustrative display with transparent openings that overlap a sensor in accordance with an embodiment. The pixel removal region 332 includes display pixel regions 322 and high-transmittance areas 324. As shown, the display may include a plurality of pixels. In FIG. 21, there are a plurality of red pixels (R), a plurality of blue pixels (B), and a plurality of green pixels (G). The red, blue, and green pixels may be arranged in any desired pattern. The red, blue, and green pixels occupy pixel regions 322. In high-transmittance areas 324, no pixels are included in the display (even though pixels would be present if the normal pixel pattern was followed).

As shown in FIG. 21, display 14 may include an array of high-transmittance areas 324. Each high-transmittance area 324 may have an increased transparency compared to pixel region 322. Therefore, the high-transmittance areas 324 may sometimes be referred to as transparent windows 324, transparent display windows 324, transparent openings 324, transparent display openings 324, etc. The transparent display windows 324 may be referred to as transparent display windows in the active area of the display. The transparent display windows may allow for light to be transmitted to an underlying sensor, as shown in FIG. 20. The transparency of high-transmittance areas 324 (for visible and/or infrared light) may be greater than 25%, greater than 30%, greater than 40%, greater than 50%, greater than 60%, greater than 70%, greater than 80%, greater than 90%, etc. The transparency of transparent openings 324 may be greater than the transparency of pixel region 322. The transparency of pixel region 322 may be less than 25%, less than 20%, less than 10%, less than 5%, etc. The pixel region 322 may sometimes be referred to as opaque display region 322, opaque region 322, opaque footprint 322, etc. Opaque region 322 includes light emitting pixels R, G, and B, and blocks light from passing through the display to an underlying sensor 13.

The pattern of pixels (322) and transparent openings (324) in FIG. 21 is merely illustrative. In FIG. 21, discrete transparent openings 324 are depicted. However, it should be understood that these transparent openings may form larger, unitary transparent openings if desired.

In FIG. 21, the display edge may be parallel to the X axis or the Y axis. The front face of the display may be parallel to the XY plane such that a user of the device views the front face of the display in the Z direction. In FIG. 21, every other subpixel may be removed for each color. The resulting pixel configuration has 50% of the subpixels removed. In FIG. 21, the remaining pixels follow a zig-zag pattern across the display (with two green sub-pixels for every one red or blue sub-pixel). In FIG. 21, the sub-pixels are angled relative to the edges of the display (e.g., the edges of the sub-pixels are at non-zero, non-orthogonal angles relative to the X-axis and Y-axis). This example is merely illustrative. If desired, each individual subpixel may have edges parallel to the display edge, a different proportion of pixels may be removed for different colors, the remaining pixels may follow a different pattern, etc.

To provide a uniform distribution of subpixels across the display surface, an intelligent pixel removal process may be implemented that systematically eliminates the closest subpixel of the same color (e.g., the nearest neighbor of the same color may be removed).

The aforementioned techniques to mitigate diffraction artifacts (e.g., spatial randomization of routing paths, spatial randomization of via locations, circular opaque LED and via patches, circular black masking layer openings, apodization, and phase randomization) may all be used in an OLED display if desired.

In an OLED display, the anode of each pixel may contribute to the opaque footprint of the display. The anode shapes may therefore be randomized in the display. For example, in the normal display region 334, the display may have one anode shape for each color of sub-pixel (e.g., all the red sub-pixels have an anode of a first shape, all the green sub-pixels have an anode of a second shape, and all the blue sub-pixels have an anode of a third shape). In the locally modified region 332, the display may have different (random) shapes for anodes of a single color. There may be a plurality of unique anode shapes for the green sub-pixels (e.g., at least two unique shapes, at least three unique shapes, at least five unique shapes, at least eight unique shapes, at least ten unique shapes, at least twenty unique shapes, at least fifty unique shapes, etc.), a plurality of unique anode shapes for the red sub-pixels (e.g., at least two unique shapes, at least three unique shapes, at least five unique shapes, at least eight unique shapes, at least ten unique shapes, at least twenty unique shapes, at least fifty unique shapes, etc.), and a plurality of unique anode shapes for the blue sub-pixels (e.g., at least two unique shapes, at least three unique shapes, at least five unique shapes, at least eight unique shapes, at least ten unique shapes, at least twenty unique shapes, at least fifty unique shapes, etc.).

Each OLED display pixel may include both a thin-film transistor layer and an emissive layer (with a similar footprint as the anode). Each emissive layer portion may have associated circuitry on the thin-film transistor layer that controls the magnitude of light emitted from that emissive layer portion. Both the emissive layer and thin-film transistor layer may have corresponding sub-pixels within the pixel. Each sub-pixel may be associated with a different color of light (e.g., red, green, and blue). The emissive layer portion for a given sub-pixel does not necessarily need to have the same footprint as its associated thin-film transistor layer portion. Hereinafter, the term sub-pixel may sometimes be used to refer to the combination of an emissive layer portion and a thin-film transistor layer portion. Additionally, the thin-film transistor layer may be referred to as having thin-film transistor sub-pixels (e.g., a portion of the thin-film transistor layer that controls a respective emissive area, sometimes referred to as thin-film transistor layer pixels, thin-film transistor layer sub-pixels or simply sub-pixels) and the emissive layer may be referred to as having emissive layer sub-pixels (sometimes referred to as emissive pixels, emissive sub-pixels or simply sub-pixels).

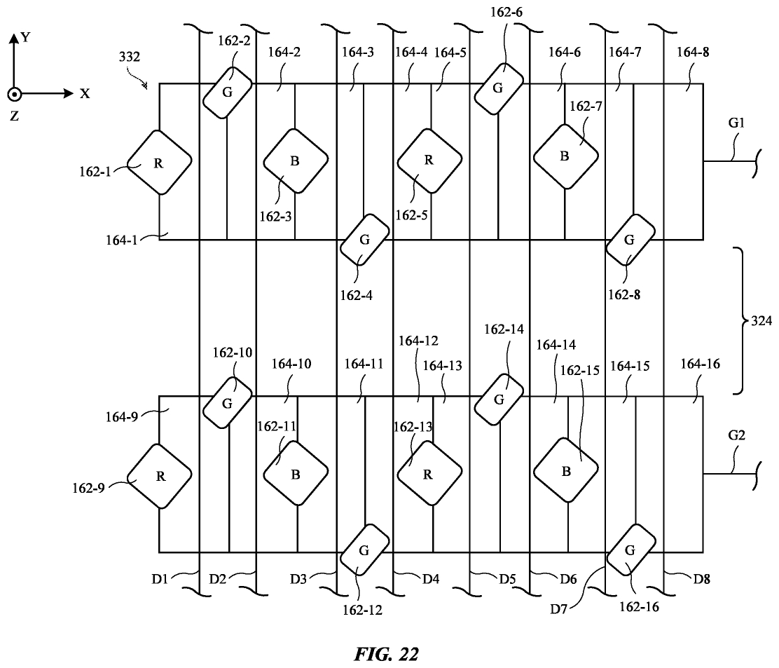

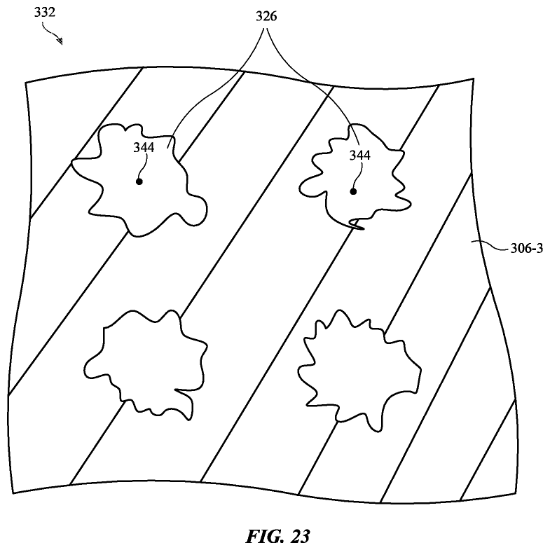

As shown in FIG. 22, the pixel removal region 332 may include emissive sub-pixels 162 such as red (R), green (G), and blue (B) emissive sub-pixels 162. The emissive sub-pixels 162 have the same arrangement as shown in FIG. 21 (e.g., horizontal zig-zag arrangement). Each emissive sub-pixel has a corresponding thin-film transistor sub-pixel. As shown in FIG. 22, red emissive sub-pixel 162-1 is controlled by a corresponding thin-film transistor sub-pixel 164-1, green emissive sub-pixel 162-2 is controlled by a corresponding thin-film transistor sub-pixel 164-2, blue emissive sub-pixel 162-3 is controlled by a corresponding thin-film transistor sub-pixel 164-3, green emissive sub-pixel 162-4 is controlled by a corresponding thin-film transistor sub-pixel 164-4, red emissive sub-pixel 162-5 is controlled by a corresponding thin-film transistor sub-pixel 164-5, green emissive sub-pixel 162-6 is controlled by a corresponding thin-film transistor sub-pixel 164-6, blue emissive sub-pixel 162-7 is controlled by a corresponding thin-film transistor sub-pixel 164-7, green emissive sub-pixel 162-8 is controlled by a corresponding thin-film transistor sub-pixel 164-8, red emissive sub-pixel 162-9 is controlled by a corresponding thin-film transistor sub-pixel 164-9, green emissive sub-pixel 162-10 is controlled by a corresponding thin-film transistor sub-pixel 164-10, blue emissive sub-pixel 162-11 is controlled by a corresponding thin-film transistor sub-pixel 164-11, green emissive sub-pixel 162-12 is controlled by a corresponding thin-film transistor sub-pixel 164-12, red emissive sub-pixel 162-13 is controlled by a corresponding thin-film transistor sub-pixel 164-13, green emissive sub-pixel 162-14 is controlled by a corresponding thin-film transistor sub-pixel 164-14, blue emissive sub-pixel 162-15 is controlled by a corresponding thin-film transistor sub-pixel 164-15, and green emissive sub-pixel 162-16 is controlled by a corresponding thin-film transistor sub-pixel 164-16. Each thin-film transistor sub-pixel controls the magnitude of light emitted from its corresponding emissive sub-pixel.

Each column of thin-film transistor sub-pixels is coupled to a respective data line. As shown in FIG. 22, data line D1 provides data to thin-film transistor sub-pixels 164-1 and 164-9, data line D2 provides data to thin-film transistor sub-pixels 164-2 and 164-10, data line D3 provides data to thin-film transistor sub-pixels 164-3 and 164-11, data line D4 provides data to thin-film transistor sub-pixels 164-4 and 164-12, data line D5 provides data to thin-film transistor sub-pixels 164-5 and 164-13, data line D6 provides data to thin-film transistor sub-pixels 164-6 and 164-14, data line D7 provides data to thin-film transistor sub-pixels 164-7 and 164-15, and data line D8 provides data to thin-film transistor sub-pixels 164-8 and 164-16.

In general, thin-film transistor sub-pixels 164 and emissive areas 162 may both have a low transmittance of light through the display stack. The areas between thin-film transistor sub-pixels 164 and emissive areas 162, however, may have a relatively high transmittance of light through the display stack. With the arrangement of FIG. 22, where each emissive sub-pixel has a corresponding thin-film transistor sub-pixel, there may be a high transmittance area 324 between rows of the thin-film transistor sub-pixels. Each row of thin-film transistor sub-pixels may be coupled to one or more corresponding gate lines. FIG. 22 shows an example where the first row of thin-film transistor sub-pixels (with sub-pixels 164-1 through 164-8) is coupled to gate line G1 and the second row of thin-film transistor sub-pixels (with sub-pixels 164-9 through 164-16) is coupled to gate line G2. Additional gate lines may be included for each row if desired.

The position, size, and/or shape of thin-film transistor sub-pixels 164 may be randomized to mitigate diffraction artifacts. For example, in the normal display region 334, the display may have regular pattern of thin-film transistor sub-pixel shapes for each color of sub-pixel (e.g., all the red sub-pixels have a thin-film transistor sub-pixel of a first shape, all the green sub-pixels have a thin-film transistor sub-pixel of a second shape, and all the blue sub-pixels have a thin-film transistor sub-pixel of a third shape). In the locally modified region 332, the display may have different (random) shapes for thin-film transistor sub-pixels of a single color. There may be a plurality of unique thin-film transistor sub-pixel shapes for the green sub-pixels (e.g., at least two unique shapes, at least three unique shapes, at least five unique shapes, at least eight unique shapes, at least ten unique shapes, at least twenty unique shapes, at least fifty unique shapes, etc.), a plurality of unique thin-film transistor sub-pixel shapes for the red sub-pixels (e.g., at least two unique shapes, at least three unique shapes, at least five unique shapes, at least eight unique shapes, at least ten unique shapes, at least twenty unique shapes, at least fifty unique shapes, etc.), and a plurality of unique thin-film transistor sub-pixel shapes for the blue sub-pixels (e.g., at least two unique shapes, at least three unique shapes, at least five unique shapes, at least eight unique shapes, at least ten unique shapes, at least twenty unique shapes, at least fifty unique shapes, etc.).

As another example, the shapes of the thin-film transistor sub-pixels may be the same in the locally modified region 332 as in the normal display region 334. However, the pattern of the thin-film transistor sub-pixels in locally modified region 332 may be different (e.g., random) in locally modified region 332 than in normal display region 334. Different TFT sub-pixel patterns may also be used in different portions of a single locally modified region 332 to mitigate diffraction artifacts.

Additional mitigation of diffraction artifacts may be achieved by randomizing etched portions of cathode layer 306-3. As shown and discussed in connection with FIG. 20, cathode 306-3 may be etched to increase transmission through the display. The cathode may be etched to have discrete openings (windows) in locally modified region 332. This is in contrast to normal display region 334, where the cathode extends uniformly without openings.

As shown in FIG. 23, the transparent windows (openings) 326 in the cathode layer 306-3 may have a randomly defined shape. Each opening 326 in FIG. 23 has a corresponding center 344. The perimeter of the transparent window may be randomly chosen. For example, a plurality of points around the center may be selected within a given range (e.g., a given distance from the center). Each transparent window may have a unique random shape in one arrangement. Alternatively, a repeating unit cell of random shapes may be repeated across the transparent windows in the display.

In locally modified region 332, there may be a plurality of unique cathode opening shapes (e.g., at least two unique shapes, at least three unique shapes, at least five unique shapes, at least eight unique shapes, at least ten unique shapes, at least twenty unique shapes, at least fifty unique shapes, etc.).

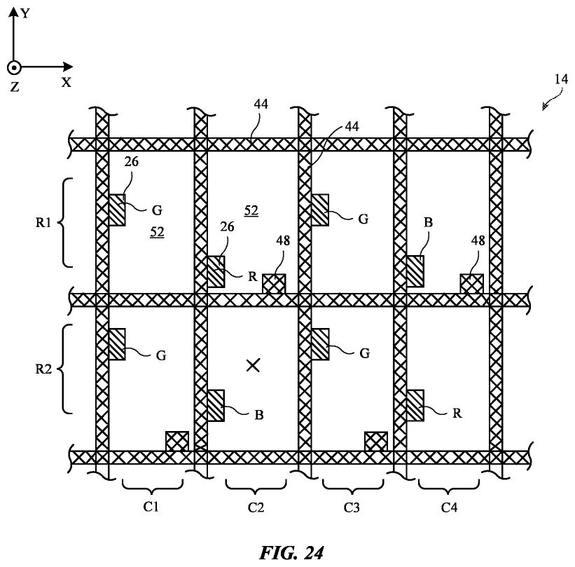

To increase the amount of light received by a sensor beneath the display (e.g., to maximize signal-to-noise ratio for the sensor), it is generally desirable for the display to be as transparent as possible. Another strategy to increase transmission through the display is to use transparent signal lines for the display (e.g., in the locally modified region 332). FIG. 24 is a top view of a display 14 that includes transparent signal lines 44 in the locally modified region of the display. In the example of FIG. 24, transparent signal lines 44 (such as data lines, gate lines, power supply lines, etc.) are arranged in a grid. The grid of signal lines defines a plurality of openings 52 (sometimes referred to as apertures 52, pixel openings 52, or pixel apertures 52). A corresponding LED 26 may be formed within each aperture 52. The display also includes a plurality of vias 48. The vias may be arranged in every other pixel within a given row, as an example.

The LEDs 26 may be arranged in a zig-zag pattern (as shown in FIG. 24). In FIG. 24, the first row (R1) includes red, green, and blue LEDs arranged in a zig-zag pattern. Similarly, the second row (R2) includes red, green, and blue LEDs arranged in a zig-zag pattern. Some of the columns (e.g., columns C1 and C3) include all green LEDs. Some of the columns (e.g., columns C2 and C4) alternate between red LEDs and green LEDs.

Signal lines 44 may be formed from a transparent conductive material such as indium tin oxide (ITO). The signal lines may transmit more than 40% of incident light (e.g., at a wavelength or wavelengths of operation for the underlying sensor such as visible light, infrared light, visible and infrared light, etc.), more than 50% of incident light, more than 60% of incident light, more than 70% of incident light, more than 80% of incident light, more than 90% of incident light, more than 95% of incident light, more than 99% of incident light, etc.

Forming signal lines 44 from a transparent material increases the transmission of light through the display. However, even if the signal lines have a high transparency, the periodic arrangement of the signal lines may cause diffractive artifacts for the underlying sensor. The transparent signal lines cause an optical phase shift due to the differing refractive indices of the layers signal lines relative to surrounding layers. Take an example where the transparent signal lines are covered by a pixel definition layer. The signal lines and pixel definition layer are formed from different materials that have different refractive indices. Light that passes through only the pixel definition layer may therefore have a phase shift relative to light that passes through the transparent signal lines and the pixel definition layer. This phase shift caused by transparent signal lines in a periodic grid results in diffractive artifacts. Additionally, to ensure the signal lines have a sufficiently low resistance, the transparent signal lines may need to be wider than if the signal lines were opaque. This may further increase the diffractive artifacts caused by the transparent signal lines.

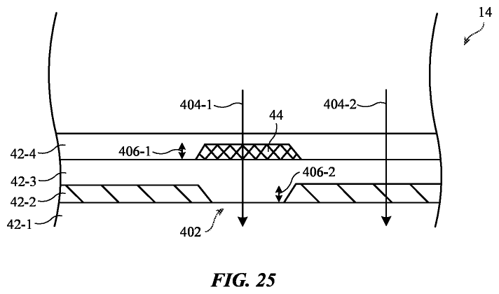

To mitigate diffractive artifacts caused by the transparent signal lines, an underlying layer may be patterned to have an inverse footprint as the transparent signal lines. FIG. 25 is a cross-sectional side view of an illustrative display with transparent signal lines 44 and a patterned phase compensation layer. As shown in FIG. 25, layers formed on substrate 42 may include layers such as layers 42-1, 42-2, 42-3, and 42-4. Layers 42-1, 42-2, 42-3, and 42-4 may sometimes be referred to as thin-film transistor circuitry layers, display layers, etc.

Layer 42-4 may be a pixel definition layer that defines a light-emitting area of each pixel. Transparent signal lines 44 may be covered by pixel definition layer 42-4. Below the transparent signal line, layers 42-2 and 42-3 are formed. Layers 42-2 and 42-3 may be dielectric layers or may be conductive layers. One or both of layers 42-2 and 42-3 may be referred to as phase compensation layers. Layers 42-2 and 42-3 may be patterned to compensate for the presence of transparent signal line 44 and mitigate phase shift that causes diffractive artifacts.

Each one of layers 42-2 and 42-3 may be a gate insulating layer for the thin-film transistor circuitry in substrate 42, an interlayer dielectric layer, a planarization layer, etc. Each one of layers 42-2 and 42-3 may be formed from silicon nitride, a silicon oxide such as silicon dioxide, polyimide, or any other desired material (e.g., any desired conductive or dielectric material).

Layer 42-2 is patterned to have an opening 402 that overlaps transparent signal line 44. In other words, the footprint of opening 402 matches the footprint of signal line 44 (e.g., a grid as in FIG. 24). In contrast, the footprint of the remaining portions of layer 42-2 matches the footprint of the area not covered by transparent signal lines 44.

The height 406-1 of signal line 44 and the height 406-2 of phase compensation layer 42-2 may be selected to ensure that light 404-1 (that passes through signal lines 44) has the same phase as light 404-2 (that does not pass through signal lines 44). The thicknesses 406-1 and 406-2 and refractive indices of layers 42-2, 42-3, 42-4 and 44 may be selected to satisfy the equation: t₁(n_{SL}−n_{PDL})=t₂(n_{DL1}−n_{DL2}), where t₁ is the thickness 406-1 of signal line 44, t₂ is the thickness 406-2 of layer 42-2, n_{SL} is the refractive index of signal line 44, n_{PDL} is the refractive index of pixel definition layer 42-4, n_{DL1} is the refractive index of layer 42-2, and n_{DL2} is the refractive index of layer 42-3. When this equation is satisfied, there is no phase shift between light 404-1 and 404-2.

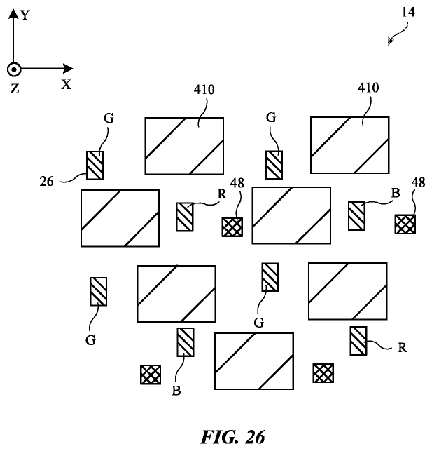

FIG. 26 is a top view of the opaque footprint of an illustrative display with transparent signal lines. As shown in FIG. 26, LEDs 26 and vias 48 may define the opaque footprint. These components may have the same layout as in FIG. 5 or FIG. 24, for example. To mitigate diffraction artifacts caused by the periodic arrangement of LEDs 26 and vias 48, dummy layers 410 may be included in the display. Dummy layers 410, sometimes referred to as dummy pattern 410, provided added phase compensation that may mitigate diffractive artifacts.

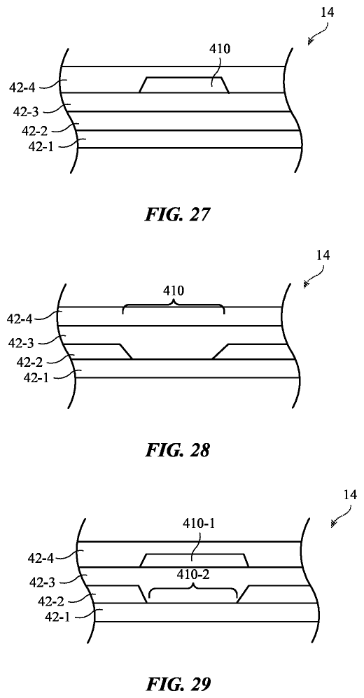

FIGS. 27-29 are cross-sectional side views showing illustrative arrangements for dummy layer 410. In the example of FIG. 27, dummy layer 410 is formed from a layer of transparent conductive material (e.g., from the same material as transparent signal lines 44 in FIGS. 24 and 25).

In another possible arrangement, shown in FIG. 28, the dummy layer may be formed by a patterned portion of layers 42-2 and 42-3. Layers 42-2 and 42-3 may be patterned dielectric layers such as a gate insulating layer for the thin-film transistor circuitry in substrate 42, an interlayer dielectric layer, a planarization layer, etc. This example is merely illustrative, and layers 42-2 and/or 42-3 may be conductive layers if desired. Each one of layers 42-2 and 42-3 may be formed from silicon nitride, a silicon oxide such as silicon dioxide, polyimide, or any other desired material (e.g., any desired conductive or dielectric material). Layer 42-2 may be patterned to include an opening that is filled by layer 42-3.

In yet another possible arrangement, shown in FIG. 29, both a dummy layer 410-1 formed from transparent conductive material (as in FIG. 27) and a patterned dielectric dummy layer 410-2 (as in FIG. 28) may be included for phase compensation.

One or more of these techniques (e.g., transparent signal lines with phase compensation and dummy layers for phase compensation) may be used with any of the aforementioned concepts.

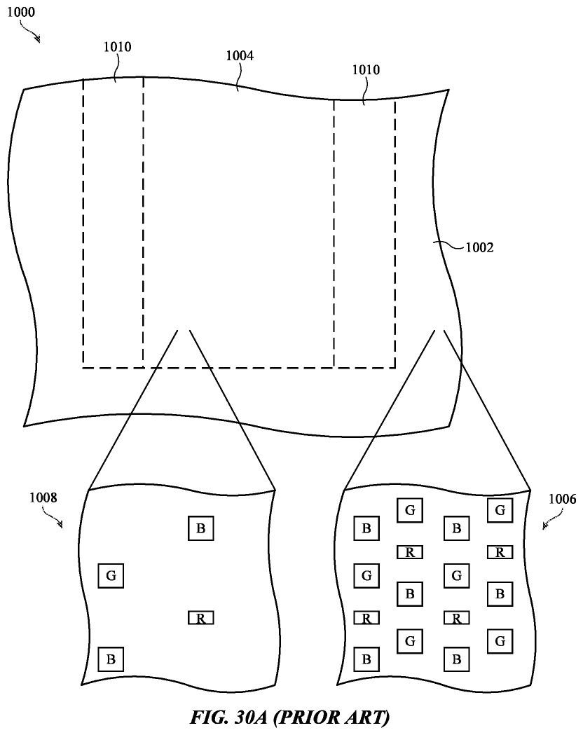

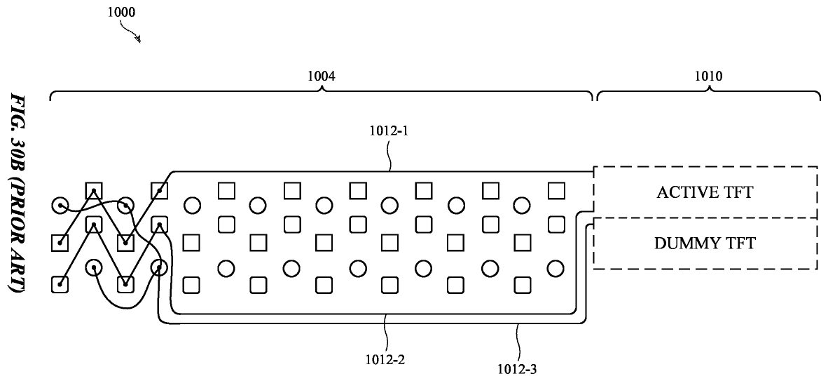

FIG. 30A is a top view of a prior art display 1000. The prior art display includes an active area 1002 and an area 1004 that overlaps a camera. As shown by inset portion 1006, active area 1002 includes red (R), blue (B), and green (G) pixels. As shown by inset portion 1008, area 1004 over a camera includes red (R), blue (B), and green (G) pixels at a lower density than in area 1002. There are 4× as many emissive pixels per unit area in area 1002 as in area 1004. Display 1000 also includes transition areas 1010 on each side of area 1004.

Thin-film transistors used to drive emissive pixels in area 1004 are positioned in transition areas 1010. As shown in FIG. 30B, transition region 1010 includes some active thin-film transistors (TFTs) that drive pixels in area 1004. Transition region 1010 also includes dummy TFTs. No TFTs are included in area 1004 (over the camera).

In FIG. 30B (a top view of the prior art display of FIG. 30A), the square pixels are green pixels, the circular pixels are red pixels, and the square pixels with rounded corners are blue pixels. Groups of four emissive pixels are shorted together and controlled using a single thin-film transistor. As shown in FIG. 30B, a first signal line 1012-1 is electrically connected to a group of four green pixels, a second signal line 1012-2 is electrically connected to a group of four blue pixels, and a third signal line 1012-3 is electrically connected to a group of four red pixels. This pattern (with signal lines controlling groups of four shorted emissive pixels) may hold true across area 1004. The same pattern is used for each row of pixels in area 1004. The signal lines depicted in FIG. 30B are schematic in nature and do not represent the actual footprint of signal lines 1012.

In accordance with an embodiment, an electronic device is provided that includes a display including a transparent substrate and a plurality of light-emitting diodes on the transparent substrate and a sensor that senses light that passes through the display, the display has a normal region that does not overlap the sensor and a locally modified region that overlaps the sensor, the locally modified region has a modification relative to the normal region that mitigates diffraction artifacts in the light sensed by the sensor.

In accordance with another embodiment, the display includes a plurality of signal lines, the signal lines are arranged in a periodic grid in the normal region, and the modification includes the signal lines being arranged in a non-periodic grid in the locally modified region.

In accordance with another embodiment, the signal lines are linear in both the normal region and the locally modified region.

In accordance with another embodiment, the display includes a plurality of signal lines, the signal lines are linear in the normal region, and the modification includes the signal lines following zig-zag paths in the locally modified region.

In accordance with another embodiment, the signal lines follow random zig-zag paths in the locally modified region.

In accordance with another embodiment, the display includes a plurality of vias, the vias are arranged in a periodic layout in the normal region, and the modification includes the vias being arranged in a non-periodic layout in the locally modified region.

In accordance with another embodiment, the plurality of vias electrically connect a common electrode for the plurality of light-emitting diodes to thin-film transistor circuitry in the transparent substrate.

In accordance with another embodiment, the display includes a plurality of vias, each via has an associated rectangular opaque footprint in the normal region, and the modification includes each via having an associated circular opaque footprint in the locally modified region.

In accordance with another embodiment, each light-emitting diode has an associated opaque footprint, each opaque footprint is rectangular in the normal region, and the modification includes each opaque footprint being circular in the locally modified region.

In accordance with another embodiment, the display includes a black masking layer that overlaps the transparent substrate, the modification includes the black masking layer having a plurality of circular openings in the locally modified region.

In accordance with another embodiment, the circular openings have the same size and consistent center-to-center spacing in the locally modified region.

In accordance with another embodiment, the circular openings have different sizes and a plurality of different center-to-center spacings in the locally modified region.

In accordance with another embodiment, the display includes a black masking layer that overlaps the transparent substrate, the black masking layer has a step change between opaque and transparent portions of the display in the normal region, and the modification includes the black masking layer having a gradual change in transparency between opaque and transparent portions of the display in the locally modified region.

In accordance with another embodiment, the modification includes a phase randomization film being included in the locally modified region.

In accordance with another embodiment, the light-emitting diodes are organic light-emitting diodes.

In accordance with another embodiment, the display includes a cathode layer for the plurality of light-emitting diodes and the modification includes including a plurality of openings of random shapes in the cathode layer in the locally modified region.

In accordance with an embodiment, an electronic device is provided that includes a display and a sensor that senses light that passes through the display, the display includes a transparent substrate, a plurality of light-emitting diodes mounted on the transparent substrate and at least one opaque component that overlaps the transparent substrate, the at least one opaque component has a periodic layout in a first portion of the display that does not overlap the sensor and a non-periodic layout in a second portion of the display that overlaps the sensor.

In accordance with another embodiment, the at least one opaque component includes a black masking layer that has the periodic layout in the first portion of the display that does not overlap the sensor and the non-periodic layout in the second portion of the display that overlaps the sensor.

In accordance with another embodiment, the at least one opaque component includes signal lines that have the periodic layout in the first portion of the display that does not overlap the sensor and the non-periodic layout in the second portion of the display that overlaps the sensor.

In accordance with another embodiment, at least one opaque component includes vias that have the periodic layout in the first portion of the display that does not overlap the sensor and the non-periodic layout in the second portion of the display that overlaps the sensor.

In accordance with an embodiment, an electronic device is provided that includes a display and a sensor that senses light that passes through the display, the display includes a transparent substrate, a plurality of light-emitting diodes mounted on the transparent substrate and a phase randomization film that overlaps the sensor.

In accordance with another embodiment, the phase randomization film has a plurality of high-index layers formed in a low-index cladding, each one of the high-index layers overlaps a respective pixel aperture in the display, and the high-index layers have random thicknesses.

In accordance with an embodiment, an electronic device is provided that includes a display and a sensor that senses light that passes through the display, the display includes a transparent substrate, a plurality of light-emitting diodes mounted on the transparent substrate, a plurality of signal lines formed from transparent conductive material, the plurality of signal lines overlap the sensor and have a first footprint, a phase compensation film that is patterned to have an opening with a second footprint that matches the first footprint.

In accordance with another embodiment, the phase compensation film includes a patterned layer on the transparent substrate.

In accordance with another embodiment, the electronic device includes a dummy pattern that creates phase shift and mitigates diffraction artifacts in the light sensed by the sensor.

The foregoing is merely illustrative and various modifications can be made by those skilled in the art without departing from the scope and spirit of the described embodiments. The foregoing embodiments may be implemented individually or in any combination.

What is claimed is:

1. An electronic device, comprising:
a display comprising a transparent substrate and a plurality of light-emitting diodes on the transparent substrate; and
a sensor that senses light that passes through the display, wherein the display has a normal region that does not overlap the sensor and a locally modified region that overlaps the sensor, wherein the locally modified region has a modification relative to the normal region that mitigates diffraction artifacts in the light sensed by the sensor.

2. The electronic device defined in claim 1, wherein the display comprises a plurality of signal lines, wherein the signal lines are arranged in a periodic grid in the normal region, and wherein the modification comprises the signal lines being arranged in a non-periodic grid in the locally modified region.

3. The electronic device defined in claim 2, wherein the signal lines are linear in both the normal region and the locally modified region.

4. The electronic device defined in claim 1, wherein the display comprises a plurality of signal lines, wherein the signal lines are linear in the normal region, and wherein the modification comprises the signal lines following zig-zag paths in the locally modified region.

5. The electronic device defined in claim 4, wherein the signal lines follow random zig-zag paths in the locally modified region.

6. The electronic device defined in claim 1, wherein the display comprises a plurality of vias, wherein the vias are arranged in a periodic layout in the normal region, and wherein the modification comprises the vias being arranged in a non-periodic layout in the locally modified region.

7. The electronic device defined in claim 6, wherein the plurality of vias electrically connect a common electrode for the plurality of light-emitting diodes to thin-film transistor circuitry in the transparent substrate.

8. The electronic device defined in claim 1, wherein the display comprises a plurality of vias, wherein each via has an associated rectangular opaque footprint in the normal region, and wherein the modification comprises each via having an associated circular opaque footprint in the locally modified region.

9. The electronic device defined in claim 1, wherein each light-emitting diode has an associated opaque footprint, wherein each opaque footprint is rectangular in the normal region, and wherein the modification comprises each opaque footprint being circular in the locally modified region.

10. The electronic device defined in claim 1, wherein the display comprises a black masking layer that overlaps the transparent substrate, wherein the modification comprises the black masking layer having a plurality of circular openings in the locally modified region.

11. The electronic device defined in claim 10, wherein the circular openings have the same size and consistent center-to-center spacing in the locally modified region.

12. The electronic device defined in claim 10, wherein the circular openings have different sizes and a plurality of different center-to-center spacings in the locally modified region.

13. The electronic device defined in claim 1, wherein the display comprises a black masking layer that overlaps the transparent substrate, wherein the black masking layer has a step change between opaque and transparent portions of the display in the normal region, and wherein the modification comprises the black masking layer having a gradual change in transparency between opaque and transparent portions of the display in the locally modified region.

14. The electronic device defined in claim 1, wherein the modification comprises a phase randomization film being included in the locally modified region.

15. The electronic device defined in claim 1, wherein the light-emitting diodes are organic light-emitting diodes.

16. The electronic device defined in claim 1, wherein the display includes a cathode layer for the plurality of light-emitting diodes and wherein the modification comprises including a plurality of openings of random shapes in the cathode layer in the locally modified region.

17. An electronic device, comprising:
a display; and
a sensor that senses light that passes through the display, wherein the display comprises:
a transparent substrate;
a plurality of light-emitting diodes mounted on the transparent substrate; and
at least one opaque component that overlaps the transparent substrate, wherein the at least one opaque component has a periodic layout in a first portion of the display that does not overlap the sensor and a non-periodic layout in a second portion of the display that overlaps the sensor.

18. The electronic device defined in claim 17, wherein the at least one opaque component comprises a black masking layer that has the periodic layout in the first portion of the display that does not overlap the sensor and the non-periodic layout in the second portion of the display that overlaps the sensor.

19. The electronic device defined in claim 17, wherein the at least one opaque component comprises signal lines that have the periodic layout in the first portion of the display that does not overlap the sensor and the non-periodic layout in the second portion of the display that overlaps the sensor.

20. The electronic device defined in claim 17, wherein the at least one opaque component comprises vias that have the periodic layout in the first portion of the display that does not overlap the sensor and the non-periodic layout in the second portion of the display that overlaps the sensor.

21. An electronic device, comprising:
a display; and
a sensor that senses light that passes through the display, wherein the display comprises:
a transparent substrate;
a plurality of light-emitting diodes mounted on the transparent substrate; and
a phase randomization film that overlaps the sensor.

22. The electronic device defined in claim 21, wherein the phase randomization film has a plurality of high-index layers formed in a low-index cladding, wherein each one of the high-index layers overlaps a respective pixel aperture in the display, and wherein the high-index layers have random thicknesses.

23. An electronic device, comprising:
a display; and
a sensor that senses light that passes through the display, wherein the display comprises:
a transparent substrate;
a plurality of light-emitting diodes mounted on the transparent substrate;
a plurality of signal lines formed from transparent conductive material, wherein the plurality of signal lines overlap the sensor and have a first footprint;
a phase compensation film that is patterned to have an opening with a second footprint that matches the first footprint.

24. The electronic device defined in claim 23, wherein the phase compensation film comprises a patterned layer on the transparent substrate.

25. The electronic device defined in claim 23, further comprising:
a dummy pattern that creates phase shift and mitigates diffraction artifacts in the light sensed by the sensor.
